(19) United States
(12) Patent Application Publication
(10) Pub. No.: US 2026/0096171 A1
(43) Pub. Date: Apr. 2, 2026

(54) SEMICONDUCTOR DEVICES WITH SIDEWALL SPACERS ON FIELD RELIEF DIELECTRIC LAYERS

(71) Applicant: TEXAS INSTRUMENTS INCORPORATED, Dallas, TX (US)

(72) Inventors: Daniel Pham, Celina, TX (US); Henry Litzmann Edwards, Garland, TX (US); Pushpa Mahalingam, Richardson, TX (US)

(21) Appl. No.: 18/901,475

(22) Filed: Sep. 30, 2024

(51) Int. Cl. H01L 29/40; H01L 29/66; H01L 29/78

(52) U.S. Cl. CPC H10D 64/111; H10D 30/0281; H10D 30/65; H10D 64/01

(57) ABSTRACT

Semiconductor devices and fabrication methods thereof are described. For example, a semiconductor device includes a semiconductor layer, a source region and a drain region disposed in the semiconductor layer, a gate electrode over the semiconductor layer between the source region and the drain region, and a gate dielectric layer between the gate electrode and the semiconductor layer. The semiconductor device also includes an insulating layer disposed between a portion of the gate electrode and the gate dielectric layer, and a spacer disposed between a sidewall of the insulating layer and the gate electrode.

### TECHNICAL FIELD

The present disclosure relates to the field of semiconductor transistors, and more particularly, but not exclusively, to laterally diffused metal oxide semiconductor (LDMOS) transistors.

### BACKGROUND

LDMOS devices are field-effect transistors (FETs) sometimes used for high power applications. In an LDMOS device, the drain and source have a relatively large spacing between them, as compared with metal oxide semiconductor (MOS) devices designed for other applications such as logic gates, and lateral diffusions are used to produce a well-controlled extended drain region. The operational performance of LDMOS devices is generally affected by parameters including, for example, a specific on-resistance (Rsp) and a breakdown voltage (BV). One design goal of LDMOS devices is to decrease Rsp and increase BV, or at least to improve one parameter without adversely affecting the other parameter.

### SUMMARY

The present disclosure describes semiconductor devices with sidewall spacers on field relief dielectric layers and methods of fabrication thereof. This summary is not an extensive overview of the disclosure. Rather, a purpose of the summary is to present some examples of the present disclosure in a simplified form as a prelude to a more detailed description that is presented later.

In some examples, a semiconductor device includes a semiconductor layer, a source region and a drain region disposed in the semiconductor layer, a gate electrode over the semiconductor layer between the source region and the drain region, a gate dielectric layer between the gate electrode and the semiconductor layer, an insulating layer disposed between a portion of the gate electrode and the gate dielectric layer, and a spacer disposed between a sidewall of the insulating layer and the gate electrode.

In some other examples, a method of fabricating a semiconductor device includes forming a source region and a drain region over a semiconductor layer, and forming an insulating layer over a first portion of the semiconductor layer between the source region and the drain region, the insulating layer having a first side facing the source region and a second side facing the drain region. A spacer is formed on the first side of the insulating layer and over a second portion of the semiconductor layer. A gate electrode is formed over (i) at least a portion of the insulating layer, (ii) the spacer and (iii) a third portion of the semiconductor layer between the spacer and the source region.

In some other examples, a semiconductor device includes a semiconductor layer, a source region and a drain region disposed in the semiconductor layer, a gate electrode over a first portion of the semiconductor layer between the source region and the drain region, a gate dielectric layer between the gate electrode and the semiconductor layer, an insulating layer disposed over the gate electrode and a second portion of the semiconductor layer, and a field plate electrode disposed over a portion of the insulating layer.

### BRIEF DESCRIPTION OF THE DRAWINGS

FIG. 1 is a cross-sectional view of a semiconductor device having a spacer disposed between a field relief dielectric layer and a gate electrode in accordance with an example of the present disclosure;

FIG. 2 is a cross-sectional view of a semiconductor device having first and second spacers disposed between a field relief dielectric layer and a gate electrode in accordance with an example of the present disclosure;

FIG. 3 is a cross-sectional view of a semiconductor device having a spacer disposed between a field relief dielectric layer and a gate electrode, and a field plate electrode disposed between a top surface of the field relief dielectric layer and the gate electrode in accordance with an example of the present disclosure;

FIG. 4 is a cross-sectional view of a semiconductor device having first and second spacers disposed between a field relief dielectric layer and a gate electrode, and a field plate electrode disposed between a top surface of the field relief dielectric layer and the gate electrode in accordance with an example of the present disclosure;

FIGS. 5A-5G are cross-sectional views of a method of fabricating a semiconductor device with a spacer disposed between a field relief dielectric layer and a gate electrode in accordance with an example of the present disclosure;

FIGS. 6A-6H are cross-sectional views of another method of fabricating a semiconductor device with a spacer disposed between a field relief dielectric layer and a gate electrode in accordance with an example of the present disclosure;

FIGS. 7A-7G are cross-sectional views of a method of fabricating a semiconductor device with a spacer disposed between a field relief dielectric layer and a gate electrode, and a field plate electrode disposed between a top surface of the field relief dielectric layer and the gate electrode in accordance with an example of the present disclosure;

FIGS. 8A-8H are cross-sectional views of another method of fabricating a semiconductor device with a spacer disposed between a field relief dielectric layer and a gate electrode, and with a field plate electrode disposed between a top surface of the field relief dielectric layer and the gate electrode in accordance with an example of the present disclosure;

FIGS. 9A and 9B are cross-sectional views of a method of fabricating a semiconductor device with first and second spacers disposed between a field relief dielectric layer and a gate electrode in accordance with an example of the present disclosure;

FIGS. 10A and 10B are cross-sectional views of a method of fabricating a semiconductor device with first and second spacers disposed between a field relief dielectric layer and a gate electrode, and with a field plate electrode disposed between a top surface of the field relief dielectric layer and the gate electrode in accordance with an example of the present disclosure;

FIG. 11 is a cross-sectional view of a semiconductor device having a field relief dielectric layer disposed between a gate electrode and a field plate electrode in accordance with an example of the present disclosure;

FIG. 12 is a cross-sectional view of a semiconductor device having a field relief dielectric layer disposed between a gate electrode and a field plate electrode, and with a spacer disposed between the gate electrode and a portion of the field relief dielectric layer in accordance with an example of the present disclosure;

FIGS. 13A-13F are cross-sectional views of a method of fabricating a semiconductor device having a field relief dielectric layer disposed between a gate electrode and a field plate electrode in accordance with an example of the present disclosure; and

FIGS. 14A-14H are cross-sectional views of a method of fabricating a semiconductor device having a field relief dielectric layer disposed between a gate electrode and a field plate electrode, and with a spacer disposed between the gate electrode and a portion of the field relief dielectric layer in accordance with an example of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about,” “approximately,” or “substantially” preceding a value mean +/−10-20 percent of the stated value. Still further, unless otherwise specified, the ordering of steps in the description and in the claims are not intended to limit sequencing of the performance of steps and thus alternate step sequencing is contemplated as appropriate.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

“Dielectric constant” as used herein with respect to a material refers to the ratio of the real part of the dielectric permittivity of that material to ε₀, the dielectric permittivity of free space. The dielectric constant may be referred to by the symbol k. A “low-k” material is defined as having a dielectric constant less than that of silicon dioxide, e.g., ≤3.5, and a “high-k” dielectric material is defined as having a dielectric constant greater than that of silicon dioxide, e.g., ≥4.

As mentioned, the operational performance of an LDMOS device is generally affected by a tradeoff between a specific on-resistance (Rsp) parameter and a breakdown voltage (BV) parameter. For example, design approaches that seek to achieve the advantage of a higher BV by increasing the body area of the device consequently lead to the disadvantage of a higher Rsp. Similarly, design approaches that seek to decrease Rsp generally come at the cost of decreasing the BV rating. Accordingly, LDMOS design approaches that effectively manage this tradeoff provide technical advantages.

LDMOS and other power devices may utilize field relief dielectrics for tuning the Rsp and BV parameters. Approaches for field relief dielectrics for LDMOS and other power devices include local oxidation of silicon (LOCOS), shallow trench isolation (STI), and abrupt or sharp-edge step gate approaches. In the LOCOS approach, silicon is consumed to form the field relief dielectric and is not applicable in fin-type FET (FinFET) and nanosheet LDMOS structures. Further, the LOCOS approach requires multiple oxidation processing steps to remove silicon nitride (SiN) residue due to the Kooi effect. The LOCOS approach also involves high temperature oxidation, and leads to scalability issues for thickness and width. The thick thermal oxide also adds stress on the silicon substrate. In the STI approach, the silicon substrate is etched and is similarly not applicable for FinFET and nanosheet LDMOS structures. The STI approach requires multiple processing steps, and also leads to scalability issues due to oxide gap fill and planarization processing. STI regions also result in corner stress with a thin gate dielectric at the upper corners thereof, which presents reliability issues for high voltage (HV) devices. The step gate approach may also result in corner effects which can lead to reliability issues such as impact ionization and breakdown of the semiconductor substrate, which may be exacerbated for HV devices. The scalability of field relief dielectrics formed using the step gate approach are largely limited due to such corner effects. FinFET and nanosheet LDMOS structures can advantageously utilize step gate field relief dielectrics.

Further scaling of LDMOS and other power devices, including FinFET and nanosheet LDMOS structures, requires scaling of the field relief dielectric. As discussed above, FinFET and nanosheet LDMOS structures are not able to use LOCOS or STI approaches for field relief dielectrics, and thus the abrupt or sharp-edge step gate approach may be used for further scaling of LDMOS devices including the field relief dielectrics thereof. The abrupt or sharp edges of step gate field relief dielectrics, however, may lead to corner effects due to the discontinuity of dielectric permittivity where the field relief oxide forms a corner with the gate dielectric. Such corner effects should be minimized to avoid BV and reliability effects due to, e.g., impact ionization.

Various disclosed structures and methods of the present disclosure may be beneficially applied to electronic devices such as LDMOS transistors to improve reliability by reducing such effects. In some examples, a dielectric spacer is formed that fills the corner formed between a field relief oxide and a gate dielectric. The dielectric constant of the dielectric spacer can be greater than or less than that of the field relief dielectric or the gate dielectric to tailor the dielectric transition between the transistor channel and the drain to minimize corner effects. Moreover, the dielectric spacer may be a same height as, or taller or shorter than, the field relief oxide as determined to provide a beneficial effect. While such examples may be expected to provide various improvements, such as increased reliability or reduced device size, no particular result is a requirement of the present disclosure unless explicitly recited in a particular claim.

Semiconductor devices, such as LDMOS devices, are described herein which allow for improved Rsp while reducing device area through the introduction of a spacer which is disposed between a field relief dielectric and a gate electrode. The spacer may be shaped to reduce the sharp corner effects, e.g. high electric field gradients, of the field relief dielectric layer. The threshold voltage of an LDMOS increases linearly with thickness of the gate dielectric and the field relief dielectric. Use of a low dielectric constant (low-k) material for the spacer can increase the threshold voltage. The spacer, which in some examples includes a dielectric material with a different dielectric constant than the field relief dielectric, is disposed between the field relief dielectric and the gate electrode and helps to reduce the sharp or abrupt change in dielectric thickness (e.g., between the gate dielectric and the field relief dielectric). The material for the spacer may be selected to have a different dielectric constant than the field relief dielectric to further improve the threshold voltage variation across the channel. The threshold voltage may be further tuned through selection of the width and height of the spacer, and in some examples the spacer height may be greater than the height of the field relief dielectric. In some examples, first and second spacers may be disposed between the field relief dielectric and the gate electrode, with the first spacer including a dielectric material that may have a different dielectric constant than the field relief dielectric and the second spacer including a conductive material that has a different work function than the gate electrode. The combination of the first and second spacers allows for additional tuning of the threshold voltage and the shape of the electric field.

In some examples, a field plate electrode is formed that is disposed between a top surface of the field relief dielectric and the gate electrode, where the field plate electrode has a different work function than the gate electrode. In some examples, first and second spacers and the field plate electrode are provided. Having the field plate electrode with a work function that is different than that of the gate electrode allows for reducing the thickness of the field relief dielectric layer and the spacer, which facilitates scaling in FinFET and nanosheet LDMOS structures.

In some examples, an LDMOS transistor structure includes a source region, a drain region, and a field relief dielectric layer (also referred to as an insulating layer). The field relief dielectric layer has a spacer disposed on a sidewall thereof. The spacer may have a height that is greater than the height of the field relief dielectric layer. The spacer, in some examples, includes first and second spacers (also referred to as first and second spacer layers), where the first spacer is a dielectric material that may have a different dielectric constant than the field relief dielectric layer, and where the second spacer is a conductive material, e.g., a metal, that may have a different work function than a gate electrode and is formed over the device channel and the field relief dielectric layer. The gate electrode extends from the source region end toward the drain region end of the LDMOS transistor structure. In some examples, a field plate electrode is disposed between a top surface of the field relief dielectric and the gate electrode, where the gate electrode and the field plate electrode may have different work functions. The LDMOS transistor structure includes contacts to connect to the source region, the drain region and the gate electrode, along with one or more metallization levels for routing the contacts to the source region, the drain region and the gate electrode to other electrical circuitry on or off the microchip.

A process for forming an LDMOS transistor structure begins with a starting silicon wafer that includes a surface region comprising lightly doped p-type silicon, e.g., a p-type epitaxial layer. Trenches are formed surrounding an area of the silicon wafer that will provide an active region for the LDMOS transistor structure, followed by formation of an n-type drift (NDRIFT) implant region, well implant regions and a gate dielectric. A field relief dielectric layer is then formed by depositing and patterning a dielectric material, or a combination of a dielectric material and a metal or doped-polysilicon material (e.g., for a field plate electrode). A spacer is then formed around the field relief dielectric layer, e.g., on sidewalls of the field relief dielectric layer (and the field plate electrode, if present). The spacer may include a single dielectric layer, multiple dielectric layers, a combination of one or more dielectric layers and one or more conducting materials, etc. The dielectric constants and work functions for the dielectric layers and the conducting materials may be selected to shape the electric field and control the threshold voltage of the LDMOS transistor structure. A gate electrode is then formed over the device channel and the field relief dielectric layer, with the gate electrode extending from the source region end to the drain region end. Contacts to the source region, the drain region and the gate electrode are then formed, followed by one or more metallization layers for routing the contacts to the source region, the drain region and the gate electrode to other electrical circuity on or off the microchip.

The field relief dielectric may be an oxide such as silicon oxide (k≈3.9), a nitride such as silicon nitride (k≈7.5), an oxynitride such as silicon oxynitride (k≈4-7.4), a low-k dielectric such as fluorine and carbon doped silicon dioxide, a high-k dielectric such as hafnium oxide, etc. In some examples, the higher capacitance that results from a high-k dielectric may help to smooth out, e.g., reduce gradients, of the electric field at interfaces during drift region depletion in the off state.

The spacer, in some examples, includes a dielectric material with a dielectric constant that is intermediate between the dielectric constant of silicon and the dielectric constant of the field relief dielectric. This relationship may reduce the kink, or sharpness of electric field gradient change, in the equipotential lines at the interfaces, alleviating high electric field points. In some examples, the field relief dielectric is an oxide material and the spacer is a nitride or amorphous silicon carbide. Amorphous silicon carbide has a dielectric constant that is close to that of silicon (e.g., (k≈10), so dielectric-driven field peaks could be nearly eliminated with such a combination. In other examples, the spacer is formed of hafnium silicate, which has a dielectric constant close to that of silicon.

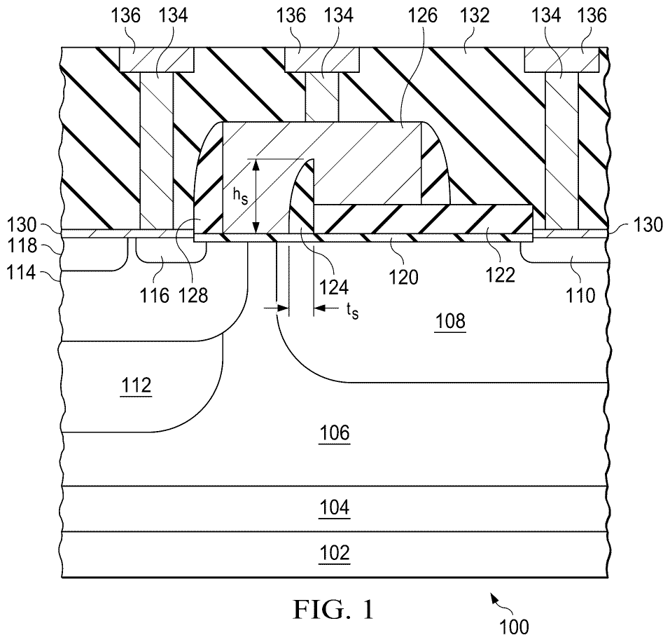

Referring now to FIG. 1, an LDMOS transistor structure 100 is shown that includes a substrate 102, a buried layer 104, an epitaxial layer 106, a drain drift region 108, a drain region 110, a well region 112, a diffused well (dwell) region 114, a source region 116, a body (or back-gate) contact region 118, a gate dielectric layer 120, a field relief dielectric layer 122, a spacer 124, a gate electrode 126, a gate spacer 128, silicide layers 130, an interlayer dielectric (ILD) layer 132, contacts 134, and metal interconnects 136. An unreferenced portion of the gate electrode 126 over the field relief dielectric layer 122 may be regarded as a field plate.

The LDMOS transistor structure 100 is formed by providing the substrate 102 and forming the buried layer 104 over the substrate 102 and forming the epitaxial layer 106 over the buried layer 104. Optionally the substrate 102 is p-type silicon, but may also be n-type silicon or silicon-on-insulator (SOI). The epitaxial layer 106 has a first conductivity type (e.g., p-type), while the buried layer 104 has a second conductivity type (e.g., n-type, and thus referred to without limitation as an n-type buried layer or NBL). The substrate 102, the buried layer 104 and the epitaxial layer 106 may be formed of silicon, and may also include other semiconducting materials.

The drain drift region 108, the drain region 110, the well region 112, the dwell region 114, the source region 116 and the body contact region 118 may each be formed using one or more ion implant processes (possibly with different energies) followed by optional anneal or thermal drive-in processes, with the use of suitable ion implant masks to form these regions in the locations shown in FIG. 1. The drain drift region 108, the drain region 110 and the source region 116 may be the second conductivity type (e.g., n-type) while the well region 112 (a shallow well region), the dwell region 114 and the body contact region 118 may be the first conductivity type (e.g., p-type).

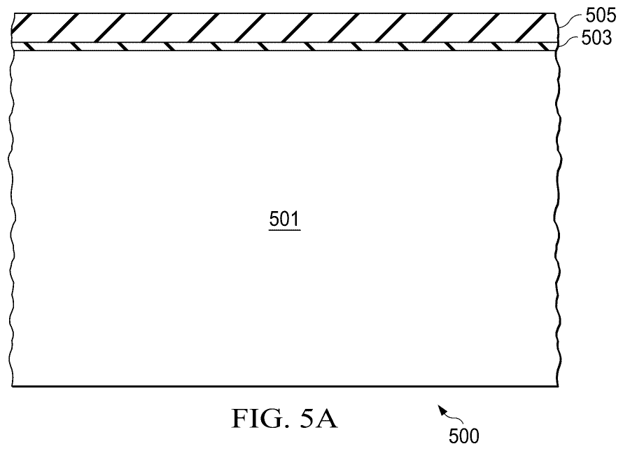

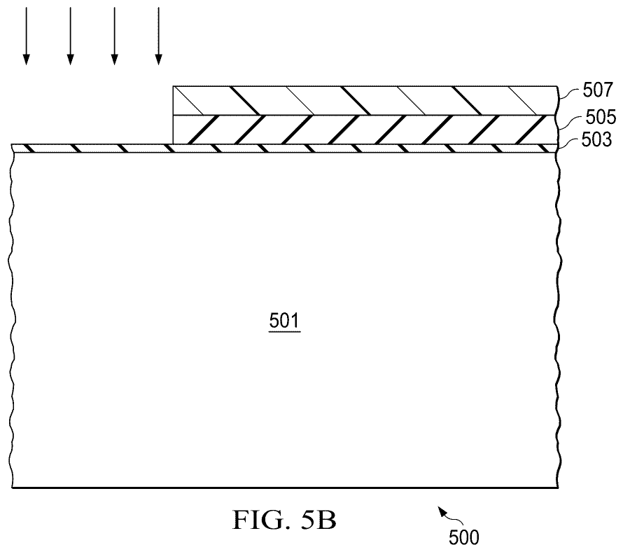

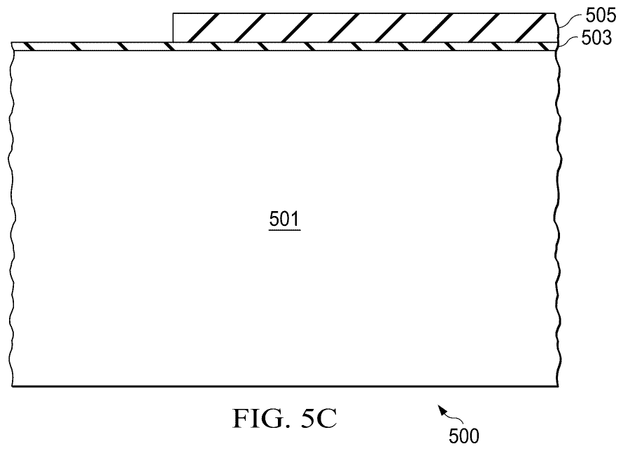

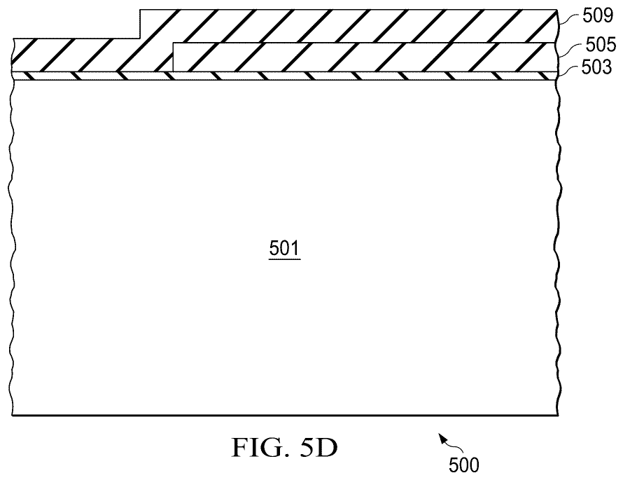

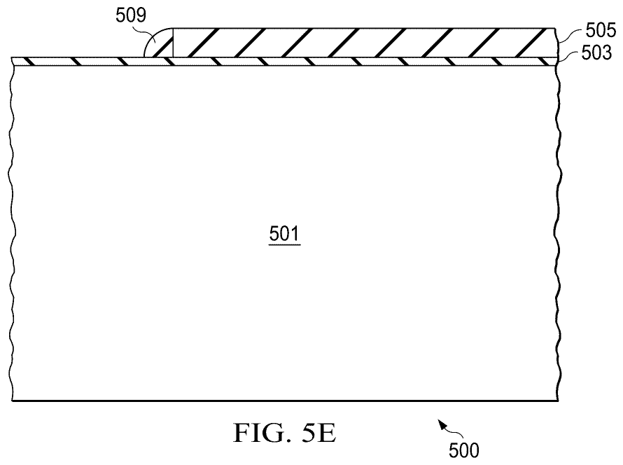

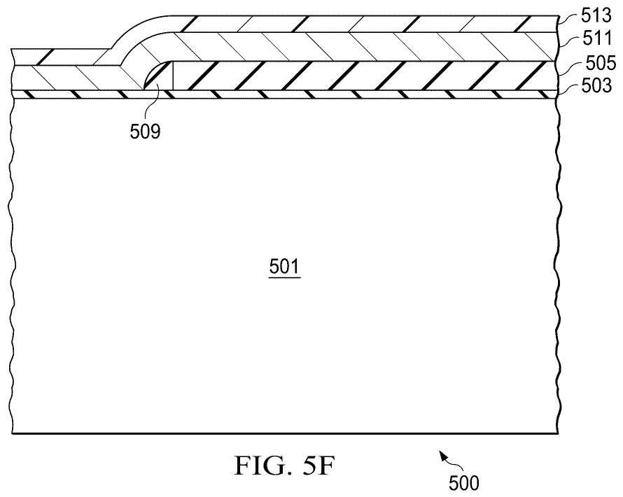

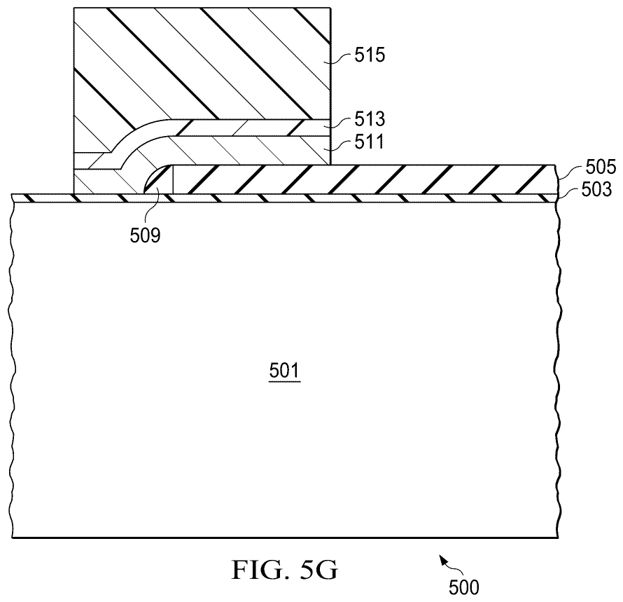

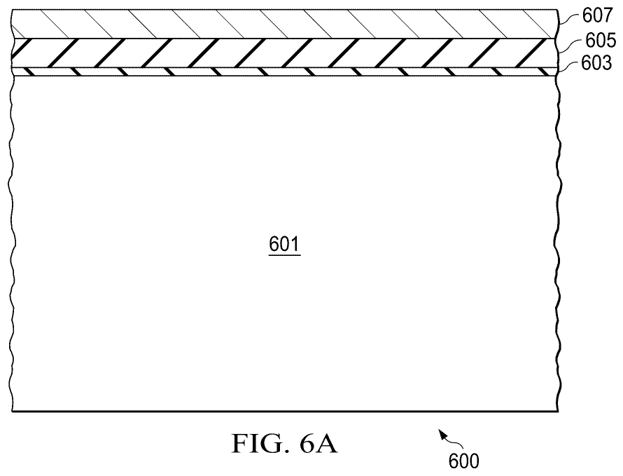

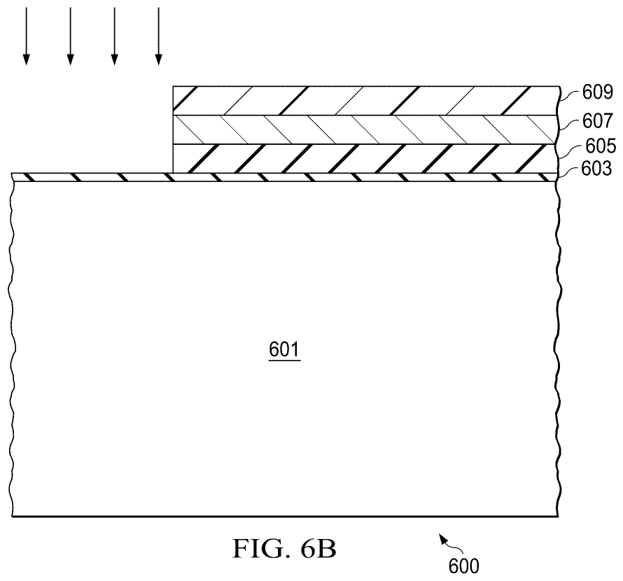

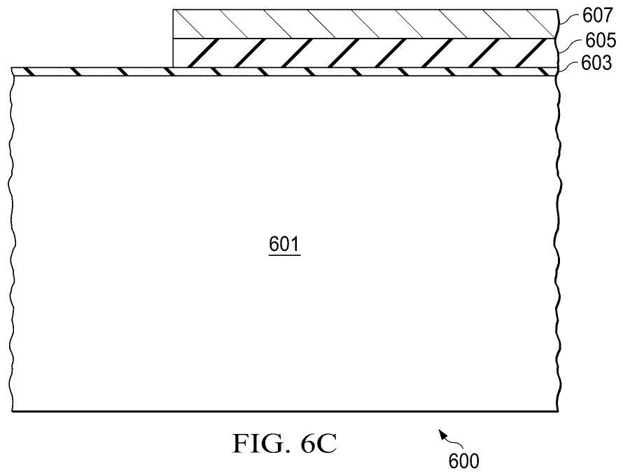

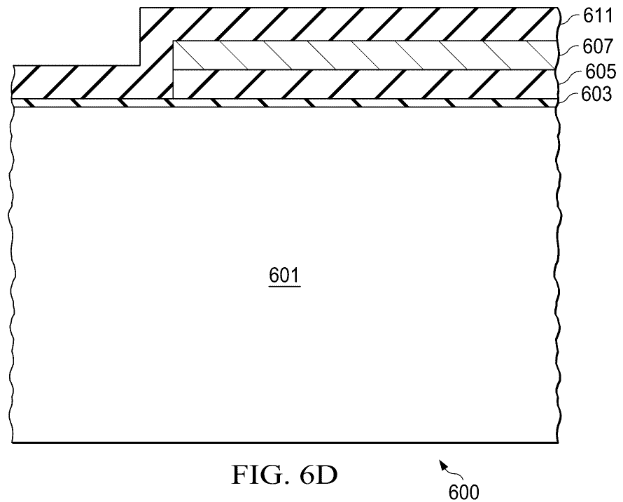

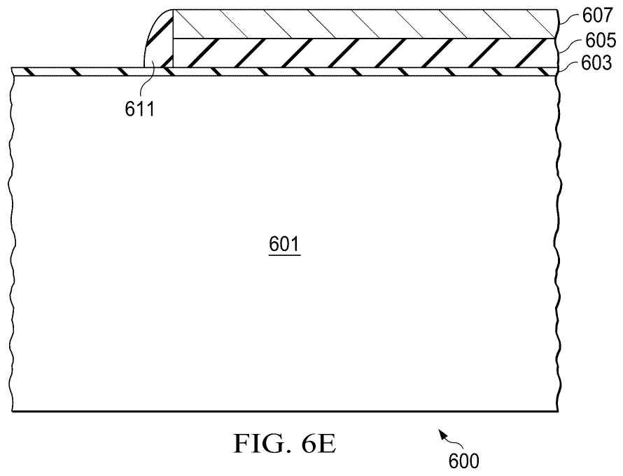

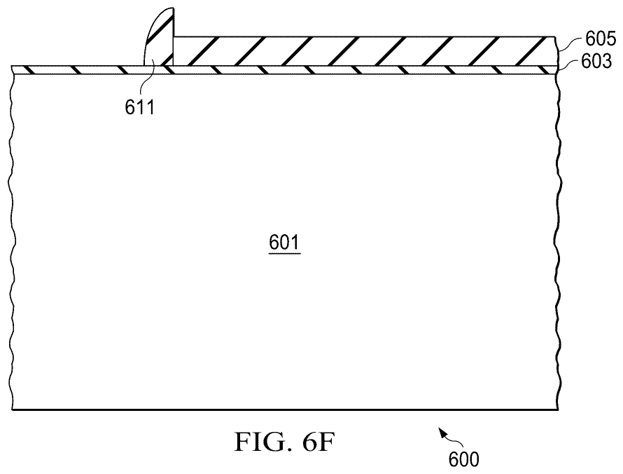

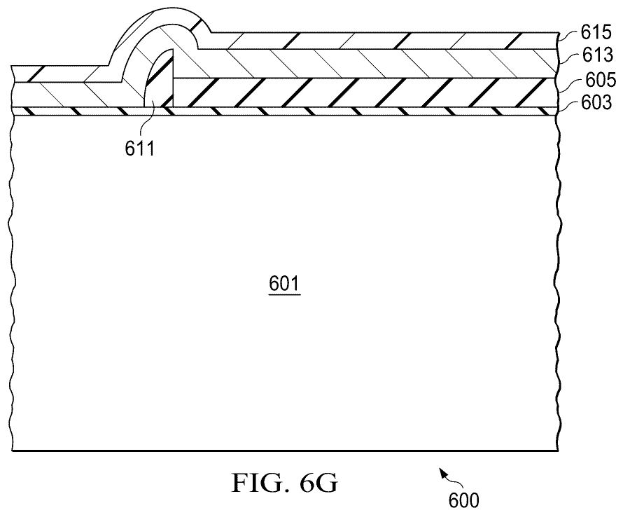

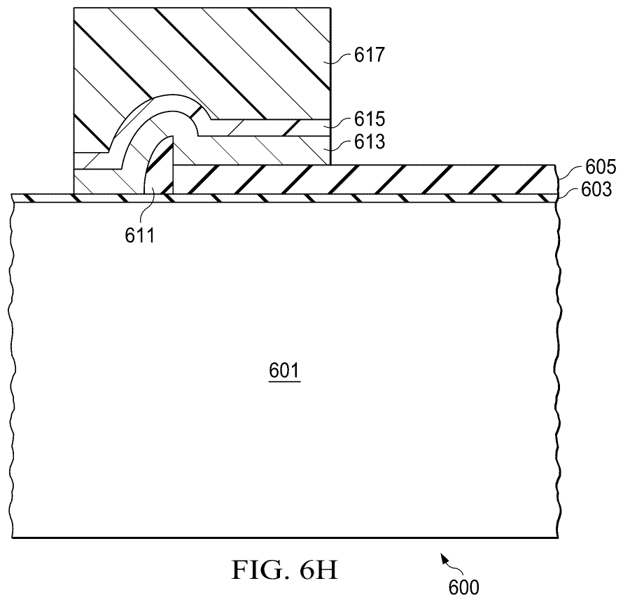

The gate dielectric layer 120, the field relief dielectric layer 122, the spacer 124 and the gate electrode 126 may be formed using the process flows described below with respect to FIGS. 5A-5G and 6A-6H.

In the LDMOS transistor structure 100, the spacer 124 has a height hₛ and a thickness (or width) tₛ, where the height hₛ and thickness tₛ may vary as desired to minimize the step gate sharp corner effect. In the example of FIG. 1, the height hₛ of the spacer 124 is greater than that of the field relief dielectric layer 122, though this is not a requirement. Such examples may reduce electric field peaking, which results in a more uniform electric field in the off state. This results in a higher BVDSS in a given drift length, which results in a smaller half pitch at the same voltage rating, further resulting in a lower Rsp and lower cost. In other examples, the height hₛ of the spacer 124 may be equal to or less than that of the field relief dielectric layer 122. The spacer 124 is formed of a material which may have a different dielectric constant than the field relief dielectric layer 122. The location of the spacer 124 can be defined using device simulation such that it is formed above a hot carrier generation area of the LDMOS transistor structure 100.

Once the gate electrode 126 is formed, the gate spacer 128 is formed. The gate spacer 128 may be formed by depositing a dielectric material such as silicon nitride, followed by an isotropic etch process such that the gate spacer 128 is disposed on the sidewalls of the gate electrode 126.

The silicide layers 130 are formed over the drain region 110, the source region 116 and the body contact region 118 (e.g., exposed silicon regions), followed by deposition of the ILD layer 132, formation of the contacts 134, and formation of the metal interconnects 136. The silicide layers 130, which may be referred to as metal silicide layers, may be formed by deposition of a layer of a metal such as titanium or nickel, which is then heated to form a metal silicide in areas where the metal contacts underlying silicon. After the formation of the silicide, the unreacted metal is removed via a wet etch process leaving the silicide layers 130 in the exposed silicon and polysilicon regions. The ILD layer 132 may be an oxide deposited using CVD, and may be doped with phosphorus or phosphorus and boron, where the dopants serve as a getter for mobile ions. The contacts 134 are formed using a pattern and etch process to form contact holes to the underlying layers, the contact holes generally being filled with a metal such as tungsten. The metal interconnects 136 are formed after the contacts 134 are formed.

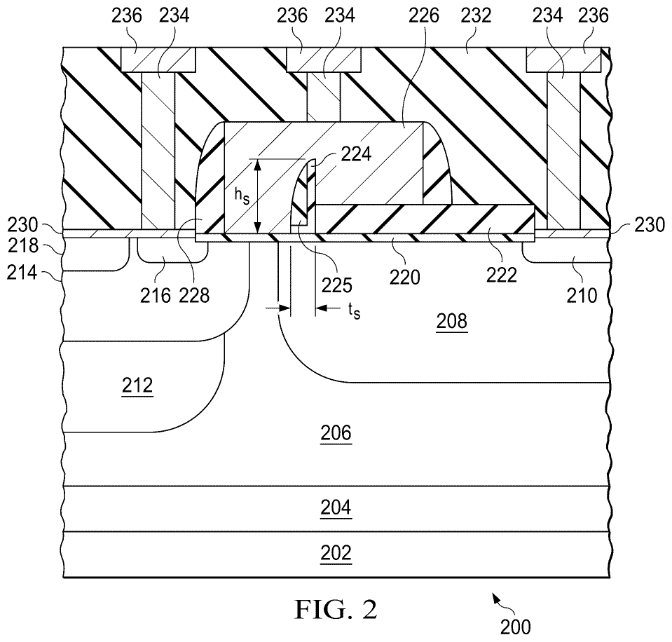

Referring now to FIG. 2, an LDMOS transistor structure 200 is shown that includes a substrate 202, a buried layer 204, an epitaxial layer 206, a drain drift region 208, a drain region 210, a well region 212, a dwell region 214, a source region 216, a body (or back-gate) contact region 218, a gate dielectric layer 220, a field relief dielectric layer 222, a first spacer 224, a second spacer 225, a gate electrode 226, a gate spacer 228, silicide layers 230, an ILD layer 232, contacts 234 and metal interconnects 236. An unreferenced portion of the gate electrode 226 over the field relief dielectric layer 222 may be regarded as a field plate. The first and second spacers 224, 225 may be considered as single non-homogenous spacer having a first nonconductive material in contact with the field relief dielectric layer 222 and a second different nonconductive material, or a conductive material, in contact with the first nonconductive material.

The LDMOS transistor structure 200 is formed using similar processing as that described above with respect to formation of the LDMOS transistor structure 100. The substrate 202 is provided, and the buried layer 204 is formed over the substrate 202 and the epitaxial layer 206 is formed over the buried layer 204. Optionally, the substrate 202 is p-type silicon, but may also be n-type silicon or SOI. The epitaxial layer 206 has a first conductivity type (e.g., p-type), while the buried layer 204 has a second conductivity type (e.g., n-type, and thus referred to without limitation as an n-type buried layer or NBL). The substrate 202, the buried layer 204 and the epitaxial layer 206 may be formed of silicon, and may also include other semiconducting materials.

The drain drift region 208, the drain region 210, the well region 212, the dwell region 214, the source region 216 and the body contact region 218 may each be formed using one or more ion implant processes (possibly with different energies) followed by optional anneal or thermal drive-in processes, with the use of suitable ion implant masks to form these regions in the locations shown in FIG. 2. The drain drift region 208, the drain region 210 and the source region 216 may be the second conductivity type (e.g., n-type) while the well region 212 (a shallow well region), the dwell region 214 and the body contact region 218 may be the first conductivity type (e.g., p-type).

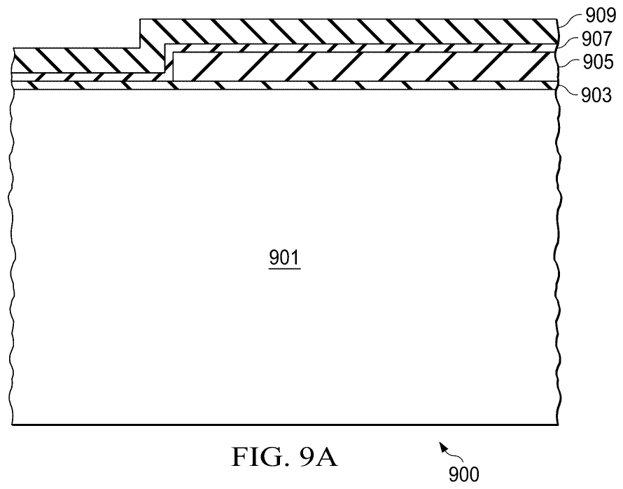

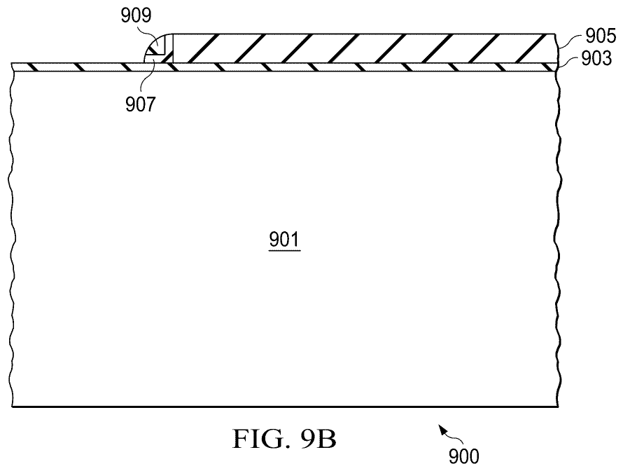

The gate dielectric layer 220, the field relief dielectric layer 222, the first spacer 224, the second spacer 225 and the gate electrode 226 may be formed using the process flows described below with respect to FIGS. 9A-9B.

In the LDMOS transistor structure 200, the first spacer 224 and the second spacer 225 may be formed of different materials. In some examples, the first spacer 224 is a first dielectric material having a dielectric constant that is different than the dielectric constant of the field relief dielectric layer 222 and the second spacer 225 is a second dielectric material having a dielectric constant that is different than both the dielectric constant of the field relief dielectric layer 222 and the dielectric constant of the first spacer 224. In other examples, the first spacer 224 is a dielectric material having a dielectric constant that is different than the dielectric constant of the field relief dielectric layer 222 and the second spacer 225 is a conducting material (e.g., a metal, polysilicon, etc.) having a work function that is different than a work function of the gate electrode 226. The first spacer 224 and the second spacer 225 have a height hₛ and a thickness (or width) tₛ, where the height hₛ and thickness tₛ may vary as desired to minimize the step gate sharp corner effect. In the example of FIG. 2, the height hₛ of the first spacer 224 and the second spacer 225 is greater than that of the field relief dielectric layer 222, though this is not a requirement. Such examples may reduce electric field peaking which results in a more uniform electric field in the off state. This results in a higher BVDSS in a given drift length, which results in a smaller half pitch at the same voltage rating, further resulting in a lower Rsp and lower cost. In other examples, the height hₛ of the first spacer 224 and the second spacer 225 may be equal to or less than that of the field relief dielectric layer 222. The location of the first spacer 224 and the second spacer 225 can be defined using device simulation such that it is formed above a hot carrier generation area of the LDMOS transistor structure 200.

Once the gate electrode 226 is formed, the gate spacer 228 is formed. The gate spacer 228 may be formed by depositing a dielectric material such as silicon nitride, followed by an isotropic etch process such that the gate spacer 228 is disposed on the sidewalls of the gate electrode 226.

The silicide layers 230 are formed over the drain region 210, the source region 216 and the body contact region 218 (e.g., exposed silicon regions), followed by deposition of the ILD layer 232, formation of the contacts 234, and formation of the metal interconnects 236. The silicide layers 230, which may be referred to as metal silicide layers, may be formed by deposition of a layer of a metal such as titanium or nickel, which is then heated to form a metal silicide in areas where the metal contacts underlying silicon. After the formation of the silicide, the unreacted metal is removed via a wet etch process leaving the silicide layers 230 in the exposed silicon and polysilicon regions. The ILD layer 232 may be an oxide deposited using CVD, and may be doped with phosphorus or phosphorus and boron, where the dopants serve as a getter for mobile ions. The contacts 234 are formed using a pattern and etch process to form contact holes to the underlying layers, the contact holes generally being filled with a metal such as tungsten. The metal interconnects 236 are formed after the contacts 234 are formed.

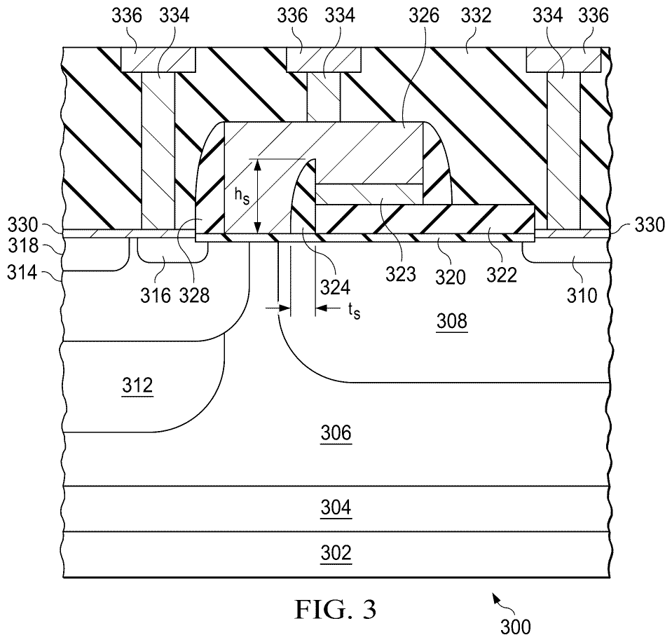

Referring now to FIG. 3, an LDMOS transistor structure 300 is shown that includes a substrate 302, a buried layer 304, an epitaxial layer 306, a drain drift region 308, a drain region 310, a well region 312, a dwell region 314, a source region 316, a body contact region 318, a gate dielectric layer 320, a field relief dielectric layer 322, a field plate electrode 323, a spacer 324, a gate electrode 326, a gate spacer 328, silicide layers 330, an ILD layer 332, contacts 334 and metal interconnects 336. An unreferenced portion of the gate electrode 326 over the field relief dielectric layer 322 may be regarded as a field plate.

The LDMOS transistor structure 300 is formed using similar processing as that described above with respect to formation of the LDMOS transistor structure 100. The substrate 302 is provided, and the buried layer 304 is formed over the substrate 302 and the epitaxial layer 306 is formed over the buried layer 304. Optionally, the substrate 302 is p-type silicon, but may also be n-type silicon or SOI. The epitaxial layer 306 has a first conductivity type (e.g., p-type), while the buried layer 304 has a second conductivity type (e.g., n-type, and thus referred to without limitation as an n-type buried layer or NBL). The substrate 302, the buried layer 304 and the epitaxial layer 306 may be formed of silicon, and may also include other semiconducting materials.

The drain drift region 308, the drain region 310, the well region 312, the dwell region 314, the source region 316 and the body contact region 318 may each be formed using one or more ion implant processes (possibly with different energies) followed by optional anneal or thermal drive-in processes, with the use of suitable ion implant masks to form these regions in the locations shown in FIG. 3. The drain drift region 308, the drain region 310 and the source region 316 may be the second conductivity type (e.g., n-type) while the well region 312 (a shallow well region), the dwell region 314 and the body contact region 318 may be the first conductivity type (e.g., p-type).

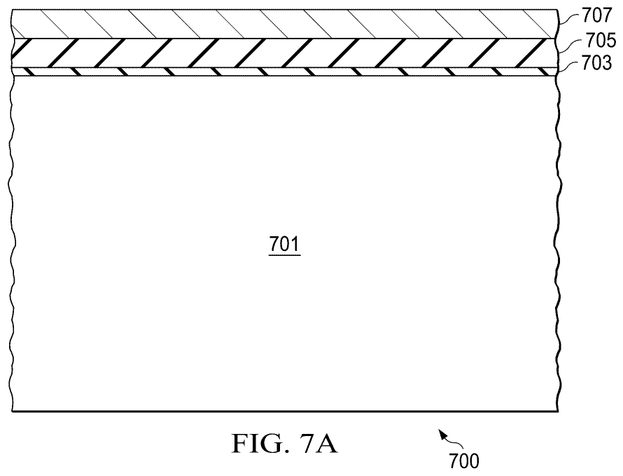

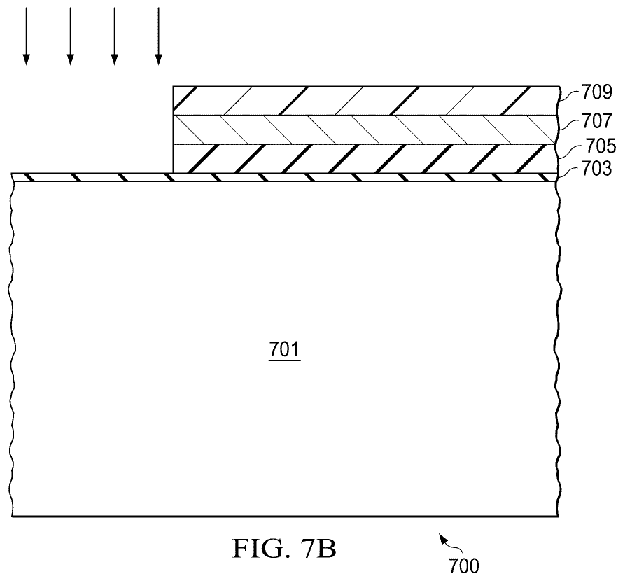

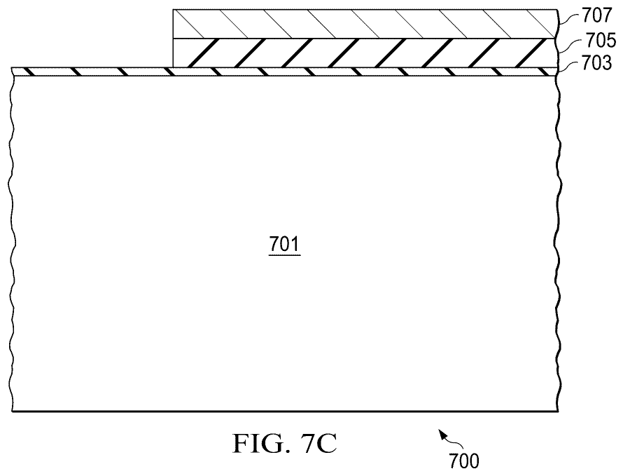

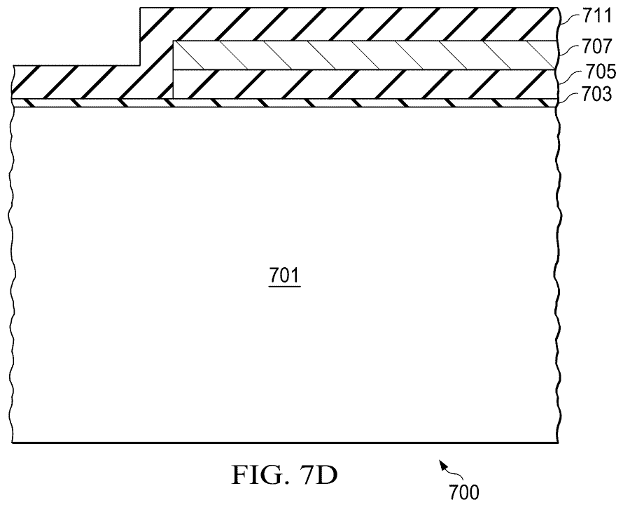

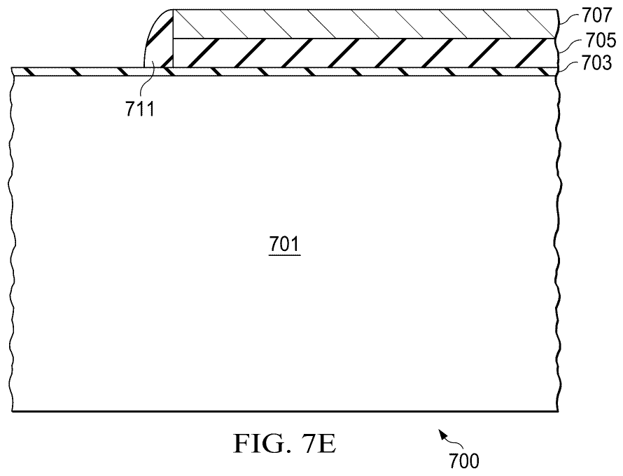

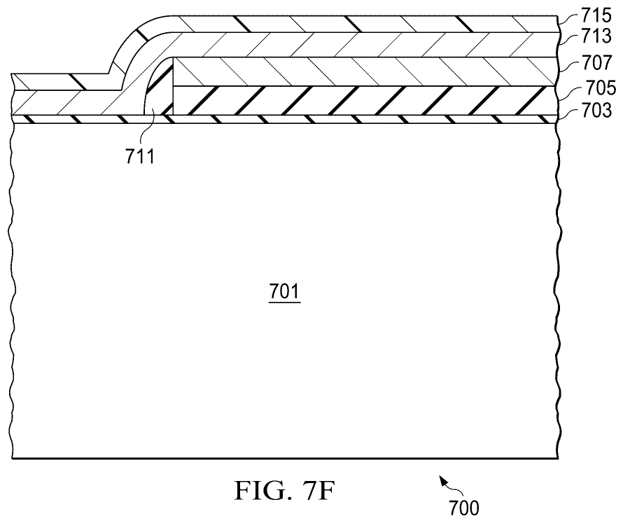

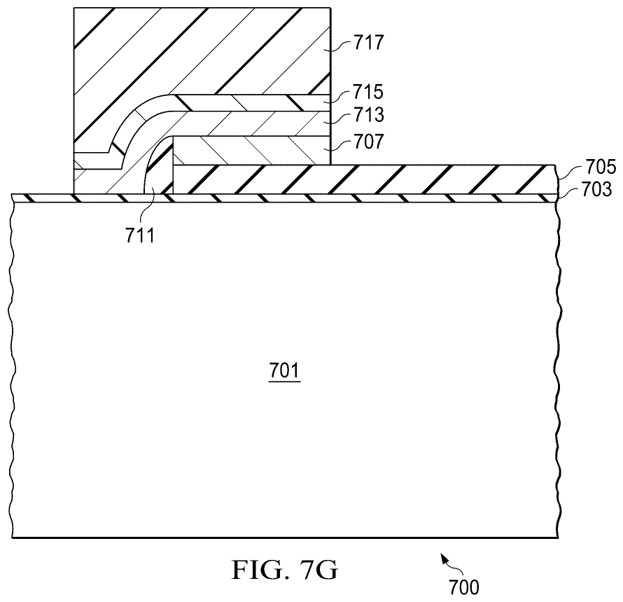

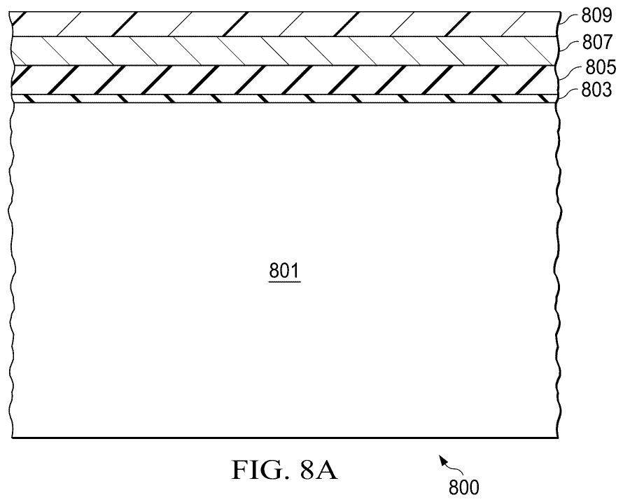

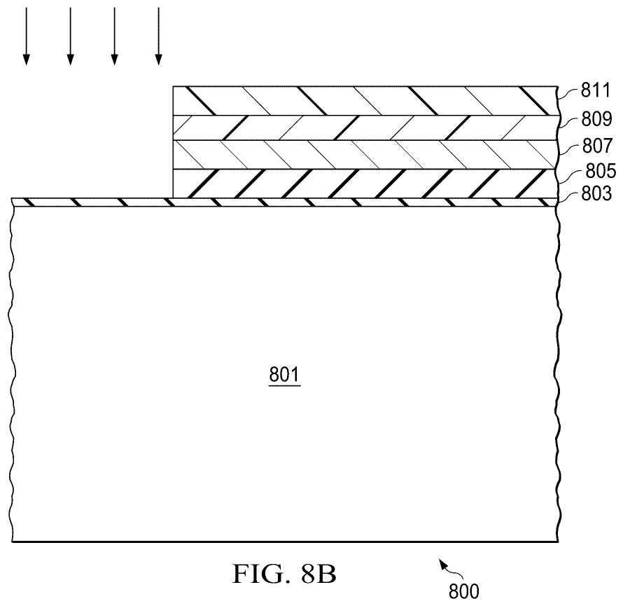

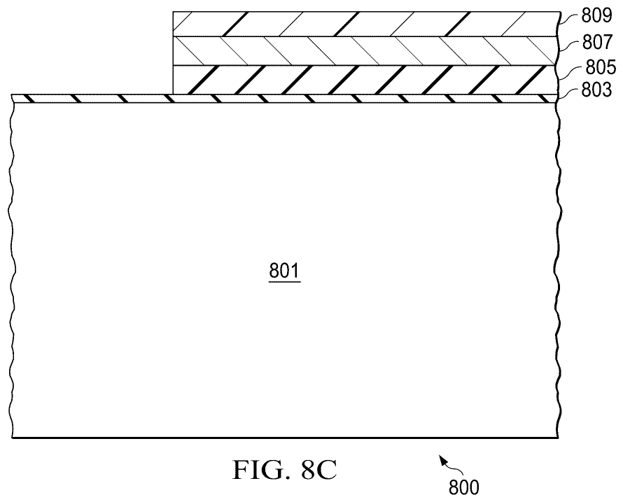

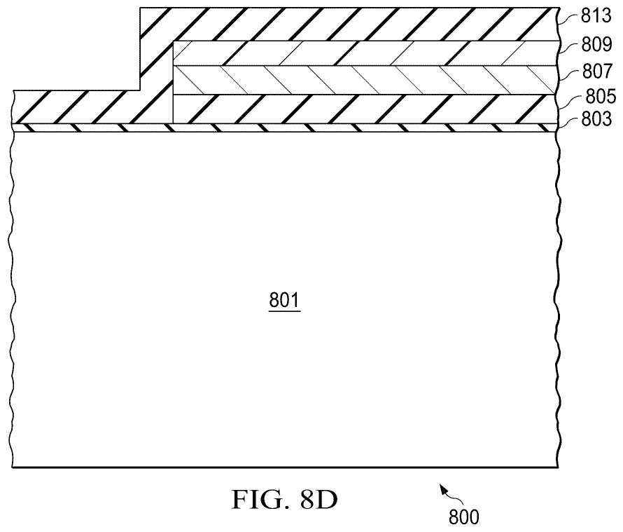

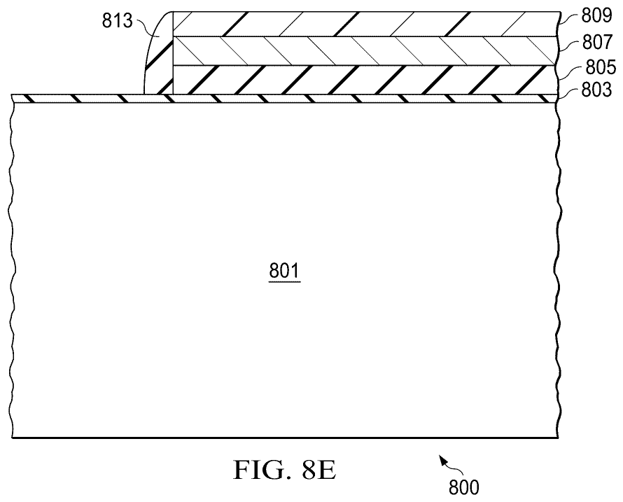

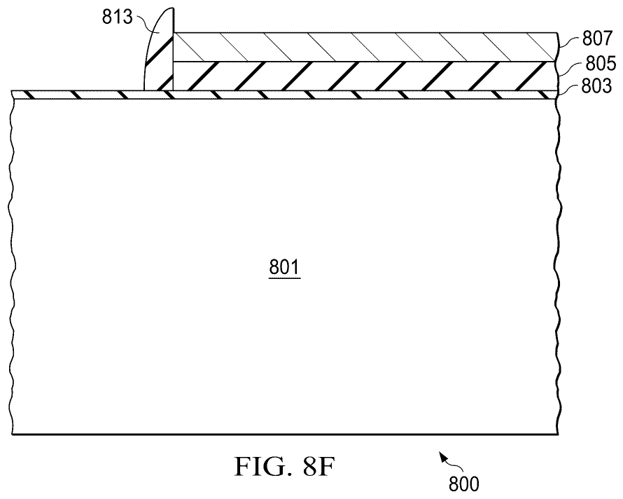

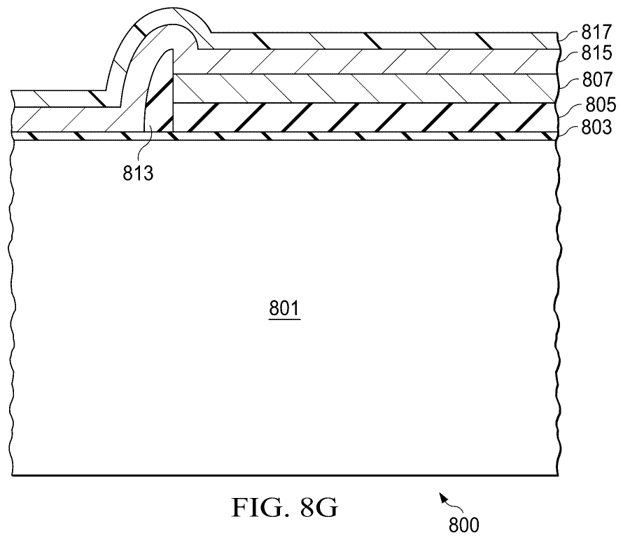

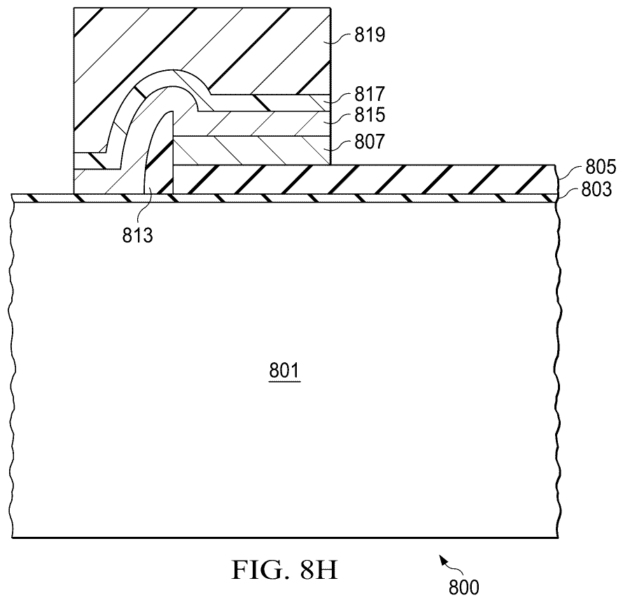

The gate dielectric layer 320, the field relief dielectric layer 322, the field plate electrode 323, the spacer 324 and the gate electrode 326 may be formed using the process flows described below with respect to FIGS. 7A-7G and 8A-8H.

In the LDMOS transistor structure 300, the field plate electrode 323, which is formed over a top surface of the field relief dielectric layer 322, has a different work function than that of the gate electrode 326. The spacer 324 has a height hₛ and a thickness (or width) tₛ, where the height hₛ and thickness tₛ may vary as desired to minimize the step gate sharp corner effect. In the example of FIG. 3, the height hₛ of the spacer 324 is greater than that of the field relief dielectric layer 322 and the field plate electrode 323, though this is not a requirement. Such examples may reduce electric field peaking, which results in a more uniform electrode field in the off state. This results in a higher BVDSS in a given drift length, which results in a smaller half pitch at the same voltage rating, further resulting in a lower Rsp and lower cost. In other examples, the height hₛ of the spacer 324 may be equal to or less than that of the field relief dielectric layer 322 and the field plate electrode 323. The spacer 324 is formed of a material which may have a different dielectric constant than the field relief dielectric layer 322. The location of the spacer 324 can be defined using device simulation such that it is formed above a hot carrier generation area of the LDMOS transistor structure 300.

Once the gate electrode 326 is formed, the gate spacer 328 is formed. The gate spacer 328 may be formed by depositing a dielectric material such as silicon nitride, followed by an isotropic etch process such that the gate spacer 328 is disposed on the sidewalls of the gate electrode 326.

The silicide layers 330 are formed over the drain region 310, the source region 316 and the body contact region 318 (e.g., exposed silicon regions), followed by deposition of the ILD layer 332, formation of the contacts 334, and formation of the metal interconnects 336. The silicide layers 330, which may be referred to as metal silicide layers, may be formed by deposition of a layer of a metal such as titanium or nickel, which is then heated to form a metal silicide in areas where the metal contacts the underlying silicon. After the formation of the silicide, the unreacted metal is removed via a wet etch process leaving the silicide layers 330 in the exposed silicon and polysilicon regions. The ILD layer 332 may be an oxide deposited using CVD, and may be doped with phosphorus or phosphorus and boron, where the dopants serve as a getter for mobile ions. The contacts 334 are formed using a pattern and etch process to form contact holes to the underlying layers, the contact holes generally being filled with a metal such as tungsten. The metal interconnects 336 are formed after the contacts 334 are formed.

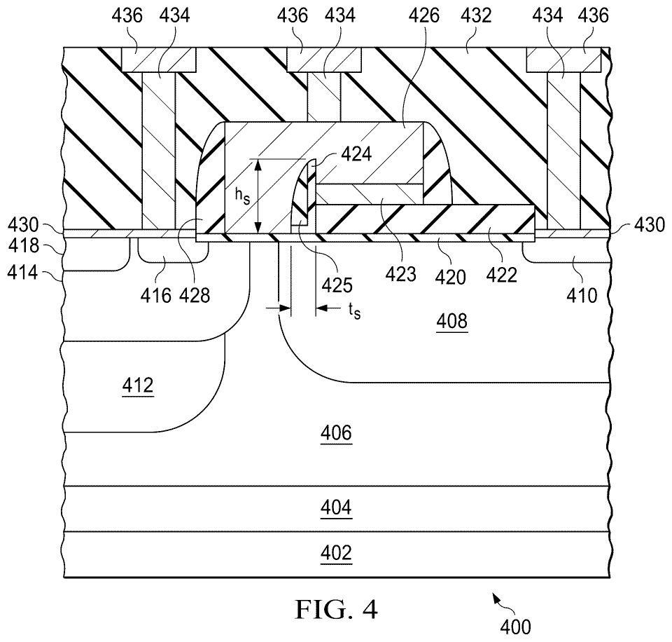

Referring now to FIG. 4, an LDMOS transistor structure 400 is shown that includes a substrate 402, a buried layer 404, an epitaxial layer 406, a drain drift region 408, a drain region 410, a well region 412, a dwell region 414, a source region 416, a body contact region 418, a gate dielectric layer 420, a field relief dielectric layer 422, a field plate electrode 423, a first spacer 424, a second spacer 425, a gate electrode 426, a gate spacer 428, silicide layers 430, an ILD layer 432, contacts 434 and metal interconnects 436. An unreferenced portion of the gate electrode 426 over the field relief dielectric layer 422 may be regarded as a field plate. The first and second spacers 424, 425 may be considered as single non-homogenous spacer having a first nonconductive material in contact with the field relief dielectric layer 422 and a second different nonconductive material, or a conductive material, in contact with the first nonconductive material.

The LDMOS transistor structure 400 is formed using similar processing as that described above with respect to formation of the LDMOS transistor structure 100. The substrate 402 is provided, and the buried layer 404 is formed over the substrate 402 and the epitaxial layer 406 is formed over the buried layer 404. Optionally, the substrate 402 is p-type silicon, but may also be n-type silicon or SOI. The epitaxial layer 406 has a first conductivity type (e.g., p-type), while the buried layer 404 has a second conductivity type (e.g., n-type, and thus referred to without limitation as an n-type buried layer or NBL). The substrate 402, the buried layer 404 and the epitaxial layer 406 may be formed of silicon, and may also include other semiconducting materials.

The drain drift region 408, the drain region 410, the well region 412, the dwell region 414, the source region 416 and the body contact region 418 may each be formed using one or more ion implant processes (possibly with different energies) followed by optional anneal or thermal drive-in processes, with the use of suitable ion implant masks to form these regions in the locations shown in FIG. 4. The drain drift region 408, the drain region 410 and the source region 416 may be the second conductivity type (e.g., n-type) while the well region 412 (a shallow well region), the dwell region 414 and the body contact region 418 may be the first conductivity type (e.g., p-type).

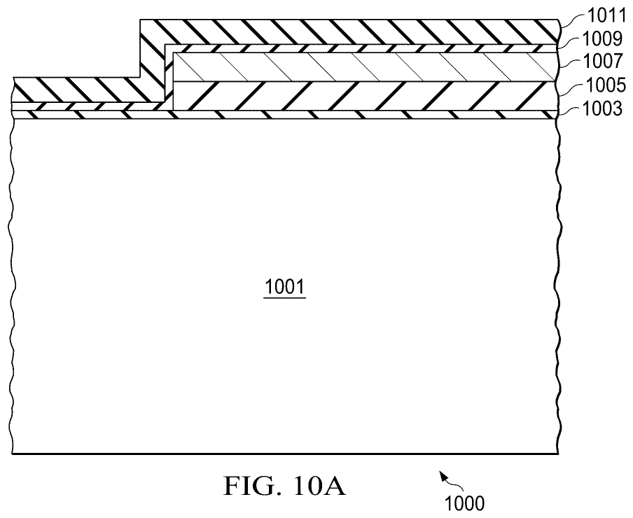

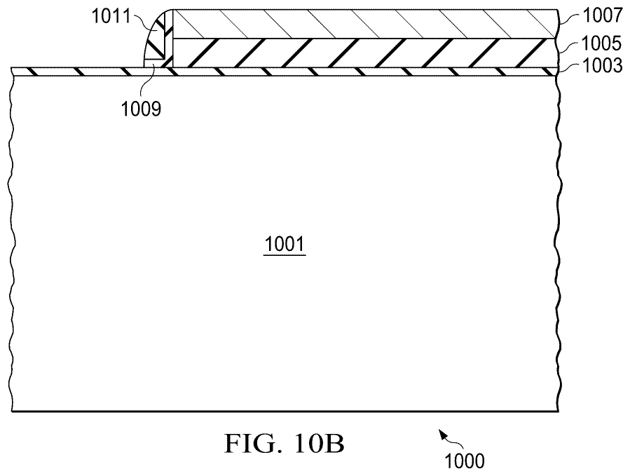

The gate dielectric layer 420, the field relief dielectric layer 422, the field plate electrode 423, the first spacer 424 and the gate electrode 426 may be formed by combining the process flows described below with respect to FIGS. 7A-7G and 8A-8H and the process flows described below with respect to FIGS. 10A-10B.

In the LDMOS transistor structure 400, the field plate electrode 423, which is formed over a top surface of the field relief dielectric layer 422, has a different work function than that of the gate electrode 426. The first spacer 424 and the second spacer 425 are formed of different materials. In some examples, the first spacer 424 is a first dielectric material having a dielectric constant that is different than the dielectric constant of the field relief dielectric layer 422 and the second spacer 425 is a second dielectric material having a dielectric constant that is different than both the dielectric constant of the field relief dielectric layer 422 and the dielectric constant of the first spacer 424. In other examples, the first spacer 424 is a dielectric material having a dielectric constant that is different than the dielectric constant of the field relief dielectric layer 422 and the second spacer 425 is a conducting material (e.g., a metal, polysilicon, etc.) having a work function that is different than a work function of the gate electrode 426.

The first spacer 424 and the second spacer 425 have a height hₛ and a thickness (or width) tₛ, where the height hₛ and thickness tₛ may vary as desired to minimize the step gate sharp corner effect. In the example of FIG. 4, the height hₛ of the first spacer 424 and the second spacer 425 is greater than that of the field relief dielectric layer 422, though this is not a requirement. Such examples may reduce electric field peaking, which results in a more uniform electric field in the off state. This results in a higher BVDSS in a given drift length, which results in a smaller half pitch at the same voltage rating, further resulting in a lower Rsp and lower cost. In other examples, the height hₛ of the first spacer 424 and the second spacer 425 may be equal to or less than that of the field relief dielectric layer 422. The location of the first spacer 424 and the second spacer 425 can be defined using device simulation such that it is formed above a hot carrier generation area of the LDMOS transistor structure 400.

Once the gate electrode 426 is formed, the gate spacer 428 is formed. The gate spacer 428 may be formed by depositing a dielectric material such as silicon nitride, followed by an isotropic etch process such that the gate spacer 428 is disposed on the sidewalls of the gate electrode 426.

The silicide layers 430 are formed over the drain region 410, the source region 416 and the body contact region 418 (e.g., exposed silicon regions), followed by deposition of the ILD layer 432, formation of the contacts 434, and formation of the metal interconnects 436. The silicide layers 430, which may be referred to as metal silicide layers, may be formed by deposition of a layer of a metal such as titanium or nickel, which is then heated to form a metal silicide in areas where the metal contacts underlying silicon. After the formation of the silicide, the unreacted metal is removed via a wet etch process leaving the silicide layers 430 in the exposed silicon and polysilicon regions. The ILD layer 432 may be an oxide deposited using CVD, and may be doped with phosphorus or phosphorus and boron, where the dopants serve as a getter for mobile ions. The contacts 434 are formed using a pattern and etch process to form contact holes to the underlying layers, the contact holes generally being filled with a metal such as tungsten. The metal interconnects 436 are formed after the contacts 434 are formed.

Referring now to FIGS. 5A-5G, a method of fabricating a semiconductor device with a spacer disposed between a field relief dielectric layer and a gate electrode is shown.

FIG. 5A shows a semiconductor structure 500 including an epitaxial layer 501 (e.g., an example of epitaxial layer 106) having a gate dielectric layer 503 (e.g., an example of the gate dielectric layer 120) formed over the epitaxial layer 501. The epitaxial layer 501 is presented in simplified form, e.g. without expressly showing various implanted regions present in a transistor device. Examples of such regions are shown in FIG. 1-4. The gate dielectric layer 503 may be a thermal oxide or a deposited high-k dielectric material. A field relief dielectric material 505 (e.g., for a field relief dielectric layer such as the field relief dielectric layer 122) is formed over the gate dielectric layer 503. The field relief dielectric material 505 may be a low-k dielectric material.

FIG. 5B shows the semiconductor structure 500 of FIG. 5A following patterning of a resist layer 507 over the field relief dielectric material 505, and following etching portions of the field relief dielectric material 505 exposed by the resist layer 507.

FIG. 5C shows the semiconductor structure 500 of FIG. 5B following removal of the resist layer 507.

FIG. 5D shows the semiconductor structure 500 of FIG. 5C following deposition of a spacer dielectric material 509 (e.g., for a spacer such as spacer 124). The spacer dielectric material 509 may be blanket deposited over the structure. The spacer dielectric material 509 may have a different dielectric constant than the field relief dielectric material 505.

FIG. 5E shows the semiconductor structure 500 of FIG. 5D following etching of the spacer dielectric material 509. The etching may be an anisotropic plasma etch process that removes the spacer dielectric material 509 from horizontal areas, while leaving the spacer dielectric material 509 on the vertical area (i.e., a sidewall) of the field relief dielectric material 505.

FIG. 5F shows the semiconductor structure 500 of FIG. 5E following formation of a gate electrode material 511 (e.g., for a gate electrode such as gate electrode 126) and a gate hard mask 513. The gate electrode material 511 and the gate hard mask 513 may be blanket deposited over the structure. The gate electrode material 511 may be polysilicon, a metal, etc. The gate hard mask 513 may be a dielectric material such as silicon nitride or silicon oxynitride, a stack of dielectric materials (e.g., for antireflecting purposes), etc.

FIG. 5G shows the semiconductor structure 500 of FIG. 5F following gate etching, where a resist layer 515 is patterned over the gate hard mask 513 and portions of the gate hard mask 513 and the gate electrode material 511 exposed by the resist layer 515 are etched. The structure of FIG. 5G may be subject to further processing to form an LDMOS transistor structure, including removal of the gate hard mask 513 and the resist layer 515, various ion implants to form source, drain, drain drift and other well regions, formation of silicide layers, formation of an ILD, and formation of contacts and metal interconnects.

While FIGS. 5A-5G show a method of fabricating a semiconductor device such that the spacer (e.g., spacer dielectric material 509) has the same height as a field relief dielectric layer (e.g., field relief dielectric material 505), this is not a requirement.

Referring now to FIGS. 6A-6H, a method of fabricating a semiconductor device with a spacer disposed between a field relief dielectric layer and a gate electrode where the spacer has a height greater than the field relief dielectric layer is shown.

FIG. 6A shows a semiconductor structure 600 including an epitaxial layer 601 (e.g., an example of epitaxial layer 106) having a gate dielectric layer 603 (e.g., an example of the gate dielectric layer 120) formed over the epitaxial layer 601. The epitaxial layer 601 is presented in simplified form, e.g., without expressly showing various implanted regions present in a transistor device. An example of such regions is shown in FIG. 2. The gate dielectric layer 603 may be a thermal oxide or a high-k dielectric material. A field relief dielectric material 605 (e.g., for a field relief dielectric layer such as the field relief dielectric layer 122) is formed over the gate dielectric layer 603. The field relief dielectric material 605 may be a low-k dielectric material. A hard mask 607 is formed over the field relief dielectric material 605.

FIG. 6B shows the semiconductor structure 600 of FIG. 6A following patterning of a resist layer 609 over the hard mask 607, and following etching portions of the hard mask 607 and the field relief dielectric material 605 exposed by the resist layer 609.

FIG. 6C shows the semiconductor structure 600 of FIG. 6B following removal of the resist layer 609.

FIG. 6D shows the semiconductor structure 600 of FIG. 6C following deposition of a spacer dielectric material 611 (e.g., for a spacer such as spacer 124). The spacer dielectric material 611 may be blanket deposited over the structure. The spacer dielectric material 611 may have a different dielectric constant than the field relief dielectric material 605.

FIG. 6E shows the semiconductor structure 600 of FIG. 6D following etching of the spacer dielectric material 611. The etching may be an anisotropic plasma etch process that removes the spacer dielectric material 611 from horizontal areas, while leaving the spacer dielectric material 611 on the vertical area (i.e., a sidewall) of the field relief dielectric material 605 and the hard mask 607.

FIG. 6F shows the semiconductor structure 600 of FIG. 6E following removal of the hard mask 607.

FIG. 6G shows the semiconductor structure 600 of FIG. 6F following formation of a gate electrode material 613 (e.g., for a gate electrode such as gate electrode 126) and a gate hard mask 615. The gate electrode material 613 and the gate hard mask 615 may be blanket deposited over the structure. The gate electrode material 613 may be polysilicon, a metal, etc. The gate hard mask 615 may be may be a dielectric material such as silicon nitride or silicon oxynitride, a stack of dielectric materials (e.g., for antireflecting purposes), etc.

FIG. 6H shows the semiconductor structure 600 of FIG. 6G following gate etching, where a resist layer 617 is patterned over the gate hard mask 615 and portions of the gate hard mask 615 and the gate electrode material 613 exposed by the resist layer 617 are etched. The structure of FIG. 6H may be subject to further processing to form an LDMOS transistor structure, including removal of the gate hard mask 615 and the resist layer 617, various ion implants to form source, drain, drain drift and other well regions, formation of silicide layers, formation of an ILD, and formation of contacts and metal interconnects. In some examples, further processing may include chemical-mechanical polishing (CMP) to reduce topography that results from the spacer dielectric material 611 extending above the field relief dielectric material 605.

Referring now to FIGS. 7A-7G, a method of fabricating a semiconductor device with a spacer disposed between a field relief dielectric layer and a gate electrode, and with a field plate electrode disposed between a top surface of the field relief dielectric layer and the gate electrode, is shown.

FIG. 7A shows a semiconductor structure 700 including an epitaxial layer 701 (e.g., an example of epitaxial layer 306) having a gate dielectric layer 703 (e.g., an example of the gate dielectric layer 320) formed over the epitaxial layer 701. The epitaxial layer 701 is presented in simplified form, e.g., without expressly showing various implanted regions present in a transistor device. An example of such regions is shown in FIG. 3. The gate dielectric layer 703 may be a high-k dielectric material. A field relief dielectric material 705 (e.g., for a field relief dielectric layer such as the field relief dielectric layer 322) is formed over the gate dielectric layer 703. The field relief dielectric material 705 may be a low-k dielectric material. A field plate electrode material 707 (e.g., for an electrode such as the field plate electrode 323) is formed over the field relief dielectric material 705.

FIG. 7B shows the semiconductor structure 700 of FIG. 7A following patterning of a resist layer 709 over the field plate electrode material 707, and following etching portions of the field plate electrode material 707 and the field relief dielectric material 705 exposed by the resist layer 709.

FIG. 7C shows the semiconductor structure 700 of FIG. 7B following removal of the resist layer 709.

FIG. 7D shows the semiconductor structure 700 of FIG. 7C following deposition of a spacer dielectric material 711 (e.g., for a spacer such as spacer 324). The spacer dielectric material 711 may be blanket deposited over the structure. The spacer dielectric material 711 may have a different dielectric constant than the field relief dielectric material 705.

FIG. 7E shows the semiconductor structure 700 of FIG. 7D following etching of the spacer dielectric material 711. The etching may be an anisotropic plasma etch process that removes the spacer dielectric material 711 from horizontal areas, while leaving the spacer dielectric material 711 on the vertical area (i.e., a sidewall) of the field relief dielectric material 705 and the field plate electrode material 707.

FIG. 7F shows the semiconductor structure 700 of FIG. 7E following formation of a gate electrode material 713 (e.g., for a gate electrode such as the gate electrode 326) and a gate hard mask 715. The gate electrode material 713 and the gate hard mask 715 may be blanket deposited over the structure. The gate electrode material 713 may be polysilicon, a metal, etc. with a different work function than the field plate electrode material 707. In some examples, the field plate electrode material 707 includes doped polysilicon, poly-silicide or another material with a mid-gap work function. The gate hard mask 715 may be a dielectric material such as silicon nitride or silicon oxynitride, a stack of dielectric materials (e.g., for antireflecting purposes), etc.

FIG. 7G shows the semiconductor structure 700 of FIG. 7F following gate etching, where a resist layer 717 is patterned over the gate hard mask 715 and portions of the gate hard mask 715, the gate electrode material 713 and the field plate electrode material 707 exposed by the resist layer 717 are etched. The structure of FIG. 7G may be subject to further processing to form an LDMOS transistor structure, including removal of the gate hard mask 715 and the resist layer 717, various ion implants to form source, drain, drain drift and other well regions, formation of silicide layers, formation of an ILD, and formation of contacts and metal interconnects.

While FIGS. 7A-7G show a method of fabricating a semiconductor device such that the spacer (e.g., spacer dielectric material 711) has the same height as a field relief dielectric layer (e.g., field relief dielectric material 705) and a field plate electrode (e.g., field plate electrode material 707) formed over a top surface of the field relief dielectric layer, this is not a requirement. Referring now to FIGS. 8A-8H, a method of fabricating a semiconductor device with a spacer disposed between a field relief dielectric layer and a gate electrode, and with a field plate electrode disposed between a top surface of the field relief dielectric layer and the gate electrode, where the spacer has a height greater than the field relief dielectric layer, is shown.

FIG. 8A shows a semiconductor structure 800 including an epitaxial layer 801 (e.g., an example of epitaxial layer 306) having a gate dielectric layer 803 (e.g., an example of the gate dielectric layer 320) formed over the epitaxial layer 801. The epitaxial layer 801 is presented in simplified form, e.g., without expressly showing various implanted regions present in a transistor device. An example of such regions is shown in FIG. 3. The gate dielectric layer 803 may be a high-k dielectric material. A field relief dielectric material 805 (e.g., for a field relief dielectric layer such as the field relief dielectric layer 322) is formed over the gate dielectric layer 803. The field relief dielectric material 805 may be a low-k dielectric material. A field plate electrode material 807 (e.g., for an electrode such as the field plate electrode 323) is formed over the field relief dielectric material 805. A hard mask 809 is formed over the field plate electrode material 807.

FIG. 8B shows the semiconductor structure 800 of FIG. 8A following patterning of a resist layer 811 over the hard mask 809, and following etching portions of the hard mask 809, the field plate electrode material 807, and the field relief dielectric material 805 exposed by the resist layer 811.

FIG. 8C shows the semiconductor structure 800 of FIG. 8B following removal of the resist layer 811.

FIG. 8D shows the semiconductor structure 800 of FIG. 8C following deposition of a spacer dielectric material 813 (e.g., for a spacer such as spacer 324). The spacer dielectric material 813 may be blanket deposited over the structure. The spacer dielectric material 813 may have a different dielectric constant than the field relief dielectric material 805.

FIG. 8E shows the semiconductor structure 800 of FIG. 8D following etching of the spacer dielectric material 813. The etching may be an anisotropic plasma etch process that removes the spacer dielectric material 813 from horizontal areas, while leaving the spacer dielectric material 813 on the vertical area (i.e., a sidewall) of the field relief dielectric material 805, the field plate electrode material 807, and the hard mask 809.

FIG. 8F shows the semiconductor structure 800 of FIG. 8E following removal of the hard mask 809.

FIG. 8G shows the semiconductor structure 800 of FIG. 8F following formation of a gate electrode material 815 (e.g., for a gate electrode such as the gate electrode 326) and a gate hard mask 817. The gate electrode material 815 and the gate hard mask 817 may be blanket deposited over the structure. The gate electrode material 815 may be polysilicon, a metal, etc. with a different work function than the field plate electrode material 807. In some examples, the field plate electrode material 807 includes doped polysilicon, poly-silicide or another material with a mid-gap work function. The gate hard mask 817 may be a dielectric material such as silicon nitride or silicon oxynitride, a stack of dielectric materials (e.g., for antireflecting purposes), etc.

FIG. 8H shows the semiconductor structure 800 of FIG. 8G following gate etching, where a resist layer 819 is patterned over the gate hard mask 817 and portions of the gate hard mask 817, the gate electrode material 815 and the field plate electrode material 807 exposed by the resist layer 819 are etched. The structure of FIG. 8H may be subject to further processing to form an LDMOS transistor structure, including various ion implants to form source, drain, drain drift and other well regions, formation of silicide layers, formation of an ILD, optionally including CMP, and formation of contacts and metal interconnects.

As discussed above with respect to FIGS. 2 and 4, in some examples first and second spacers may be formed which are disposed between a field relief dielectric layer and a gate electrode. Referring now to FIGS. 9A-9B, a method of fabricating a semiconductor device with first and second spacers disposed between a field relief dielectric layer and a gate electrode is shown.

FIG. 9A shows a semiconductor structure 900 including an epitaxial layer 901 (e.g., an example of epitaxial layer 206) having a gate dielectric layer 903 (e.g., an example of the gate dielectric layer 220) formed over the epitaxial layer 901. The epitaxial layer 901 is presented in simplified form, e.g., without expressly showing various implanted regions present in a transistor device. An examples of such regions is shown in FIG. 2. The gate dielectric layer 903 may be a high-k dielectric material. A field relief dielectric material 905 (e.g., for a field relief dielectric layer such as the field relief dielectric layer 222) is formed over the gate dielectric layer 903. The field relief dielectric material 905 may be a low-k dielectric material. The field relief dielectric material 905 is patterned over only a portion of the gate dielectric layer 903 using processing similar to that described above with respect to FIGS. 5A-5B. A first spacer layer material 907 (e.g., for a first spacer such as the first spacer 224) and a second spacer layer material 909 (e.g., for a second spacer such as the second spacer 225) are formed over the structure. The first spacer layer material 907 and the second spacer layer material 909 may be blanket deposited over the structure. In some examples, the first spacer layer material 907 and the second spacer layer material 909 are both dielectric materials, but have different dielectric constants than each other and the field relief dielectric material 905. In other examples, the first spacer layer material 907 is a dielectric material with a dielectric constant different than that of the field relief dielectric material 905 and the second spacer layer material 909 is a conducting material with a work function different than that of a gate electrode that is to be formed.

FIG. 9B shows the semiconductor structure 900 of FIG. 9A following etching of the first spacer layer material 907 and the second spacer layer material 909. The etching may be an anisotropic plasma etch process that removes the first spacer layer material 907 and the second spacer layer material 909 from horizontal areas, while leaving the first spacer layer material 907 and the second spacer layer material 909 on the vertical area (i.e., a sidewall) of the field relief dielectric material 905. The structure of FIG. 9B may be subject to further processing such as that shown in FIGS. 5F and 5G to form a gate electrode, and additional processing to form an LDMOS transistor structure, including various ion implants to form source, drain, drain drift and other well regions, formation of silicide layers, formation of an ILD, and formation of contacts and metal interconnects.

Referring now to FIGS. 10A and 10B, a method of fabricating a semiconductor device with first and second spacers disposed between a field relief dielectric layer and a gate electrode, with a field plate electrode being disposed between a top surface of the field dielectric layer and the gate electrode, is shown.

FIG. 10A shows a semiconductor structure 1000 including an epitaxial layer 1001 (e.g., an example of epitaxial layer 406) having a gate dielectric layer 1003 (e.g., an example of the gate dielectric layer 420) formed over the epitaxial layer 1001. The epitaxial layer 1001 is presented in simplified form, e.g., without expressly showing various implanted regions present in a transistor device. An example of such regions is shown in FIG. 4. The gate dielectric layer 1003 may be a high-k dielectric material. A field relief dielectric material 1005 (e.g., for a field relief dielectric layer such as the field relief dielectric layer 422) is formed over the gate dielectric layer 1003. The field relief dielectric material 1005 may be a low-k dielectric material. A field plate electrode material 1007 (e.g., for a gate electrode such as the field plate electrode 423) is formed over the field relief dielectric material 1005. The field relief dielectric material 1005 and the field plate electrode material 1007 are patterned over only a portion of the gate dielectric layer 1003 using processing similar to that described above with respect to FIGS. 7A-7B. A first spacer layer material 1009 (e.g., for a first spacer such as the first spacer 424) and a second spacer layer material 1011 (e.g., for a second spacer such as the second spacer 425) are formed over the structure. The first spacer layer material 1009 and the second spacer layer material 1011 may be blanket deposited over the structure. In some examples, the first spacer layer material 1009 and the second spacer layer material 1011 are both dielectric materials, but have different dielectric constants than each other and the field relief dielectric material 1005. In other examples, the first spacer layer material 1009 is a dielectric material with a dielectric constant different than that of the field relief dielectric material 1005 and the second spacer layer material 1011 is a conducting material with a work function different than that of a gate electrode that is to be formed.

FIG. 10B shows the semiconductor structure 1000 of FIG. 10A following etching of the first spacer layer material 1009 and the second spacer layer material 1011. The etching may be an anisotropic plasma etch process that removes the first spacer layer material 1009 and the second spacer layer material 1011 from horizontal areas, while leaving the first spacer layer material 1009 and the second spacer layer material 1011 on the vertical area (i.e., a sidewall) of the field relief dielectric material 1005 and the field plate electrode material 1007. The structure of FIG. 10B may be subject to further processing such as that shown in FIGS. 6G and 6H to form a gate electrode, and additional processing to form an LDMOS transistor structure, including various ion implants to form source, drain, drain drift and other well regions, formation of silicide layers, formation of an ILD, and formation of contacts and metal interconnects.

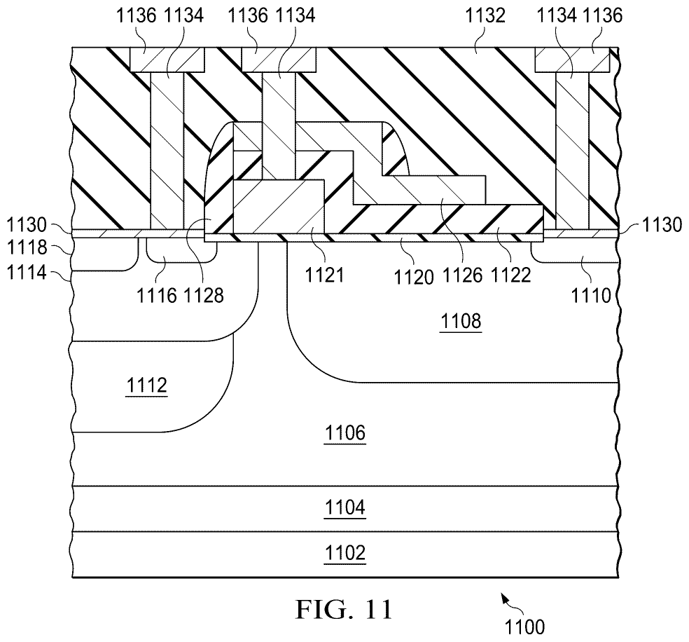

Referring now to FIG. 11, an LDMOS transistor structure 1100 is shown which includes a substrate 1102, a buried layer 1104, an epitaxial layer 1106, a drain drift region 1108, a drain region 1110, a well region 1112, a dwell region 1114, a source region 1116, a body contact region 1118, a gate dielectric layer 1120, a gate electrode 1121, a field relief dielectric layer 1122, a field plate electrode 1126, a gate spacer 1128, silicide layers 1130, an ILD layer 1132, contacts 1134 and metal interconnects 1136.

The LDMOS transistor structure 1100 is formed by providing the substrate 1102 and forming the buried layer 1104 over the substrate 1102 and forming the epitaxial layer 1106 over the buried layer 1104. The substrate 1102 and the epitaxial layer 1106 are a first conductivity type (e.g., p-type), while the buried layer 1104 is a second conductivity type (e.g., n-type, and thus referred to as an n-type buried layer or NBL). The substrate 1102, the buried layer 1104 and the epitaxial layer 1106 may be formed of silicon, and may also include other semiconducting materials.

The drain drift region 1108, the drain region 1110, the well region 1112, the dwell region 1114, the source region 1116 and the body contact region 1118 may each be formed using one or more ion implant processes (possibly with different energies) followed by optional anneal or thermal drive-in processes, with the use of suitable ion implant masks to form these regions in the locations shown in FIG. 11. The drain drift region 1108, the drain region 1110 and the source region 1116 may be the second conductivity type (e.g., n-type) while the well region 1112 (a shallow well region), the dwell region 1114 and the body contact region 1118 may be the first conductivity type (e.g., p-type).

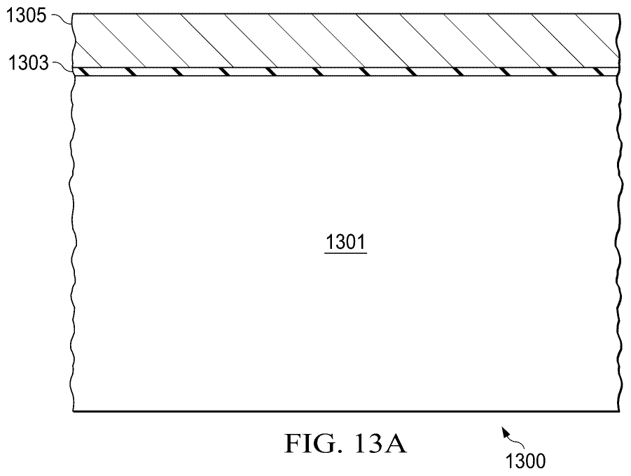

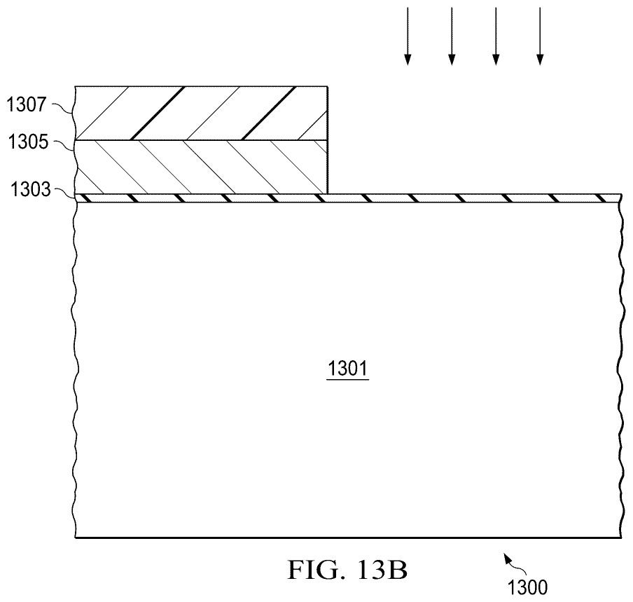

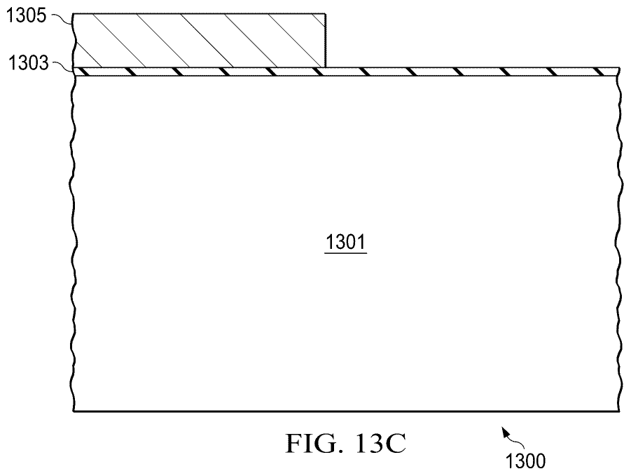

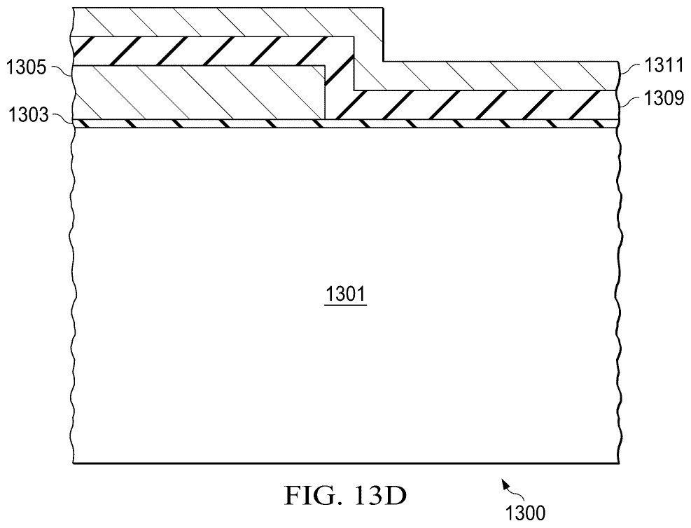

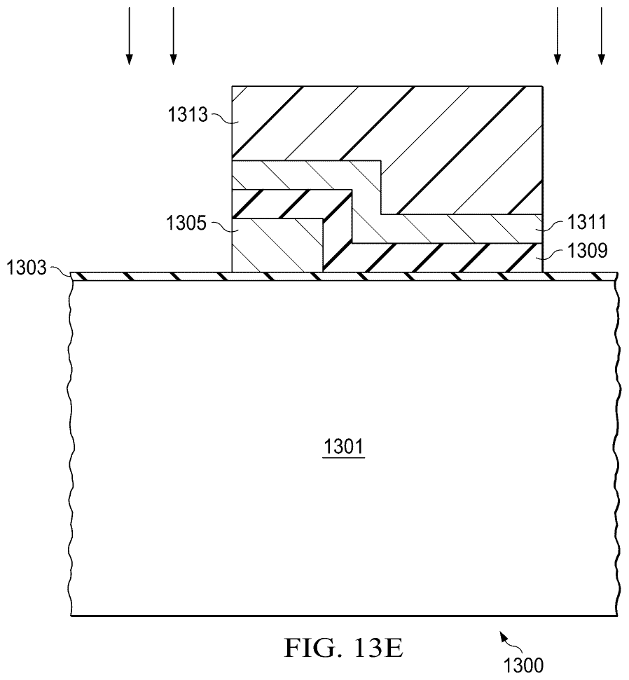

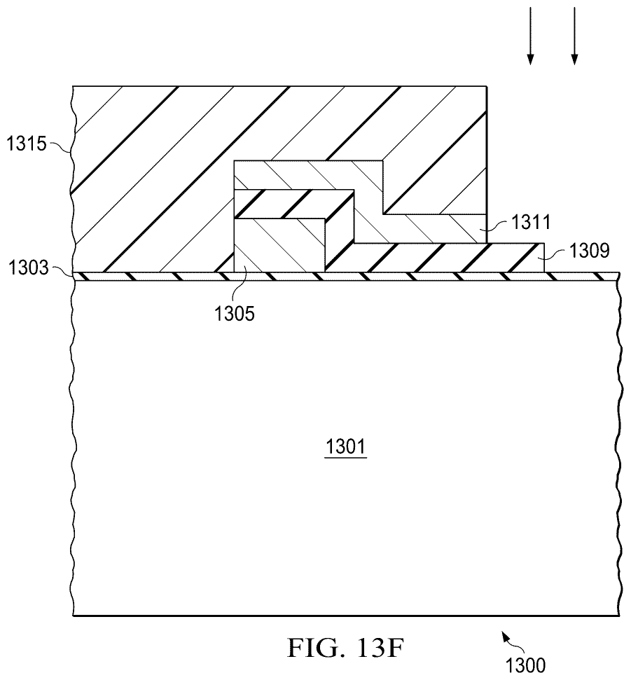

The gate dielectric layer 1120, the gate electrode 1121, the field relief dielectric layer 1122 and the field plate electrode 1126 may be formed using the process flow described below with respect to FIGS. 13A-13F.

In the LDMOS transistor structure 1100, the field relief dielectric layer 1122 is disposed between the gate electrode 1121 and the field plate electrode 1126, with the gate electrode 1121 being formed over the epitaxial layer 1106 over the channel region, extending partway over the dwell region 1114 and partway over the drain drift region 1108. The field relief dielectric layer 1122 is formed over the gate electrode 1121 and extends over the drain drift region 1108 towards the drain region 1110. The field plate electrode 1126 is formed over a portion of the field relief dielectric layer 1122. The one of the contacts 1134 for the gate is formed in a trench that extends through the field plate electrode 1126 and the field relief dielectric layer 1122 so as to be in contact with both the gate electrode 1121 and the field plate electrode 1126.

Once the field plate electrode 1126 is formed, the gate spacer 1128 is formed. The gate spacer 1128 may be formed by depositing a dielectric material such as silicon nitride, followed by an isotropic etch process such that the gate spacer 1128 is disposed on the sidewalls of the field plate electrode 1126.

The silicide layers 1130 are formed over the drain region 1110, the source region 1116 and the body contact region 1118 (e.g., exposed silicon regions), followed by deposition of the ILD layer 1132, formation of the contacts 1134, and formation of the metal interconnects 1136. The silicide layers 1130, which may be referred to as metal silicide layers, may be formed by deposition of a layer of a metal such as titanium or nickel, which is then heated to form a metal silicide in areas where the metal contacts the epitaxial layer 1106. After the formation of the silicide, the unreacted metal is removed via a wet etch process leaving the silicide layers 1130 in the exposed silicon and polysilicon regions. The ILD layer 1132 may be an oxide deposited using CVD, and may be doped with phosphorus or phosphorus and boron, where the dopants serve as a getter for mobile ions. The contacts 1134 are formed using a pattern and etch process to form contact holes to the underlying layers, the contact holes generally being filled with a metal such as tungsten. The metal interconnects 1136 are formed after the contacts 1134 are formed.

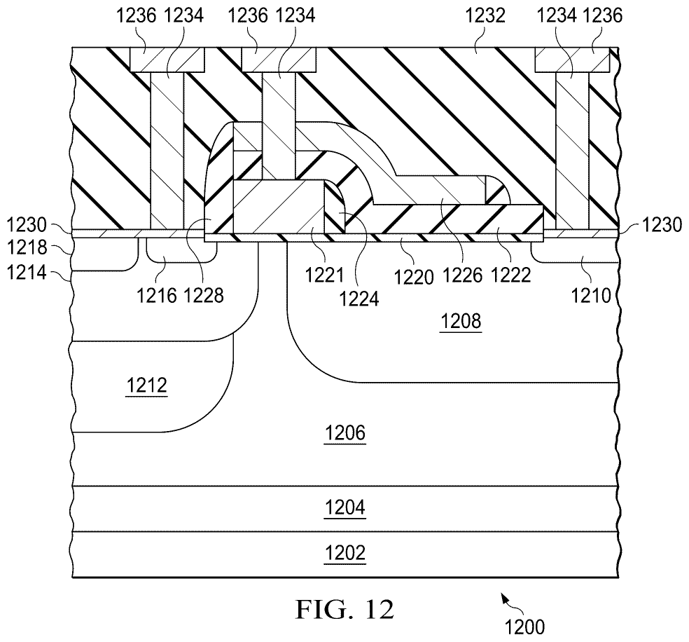

Referring now to FIG. 12, an LDMOS transistor structure 1200 is shown which includes a substrate 1202, a buried layer 1204, an epitaxial layer 1206, a drain drift region 1208, a drain region 1210, a well region 1212, a dwell region 1214, a source region 1216, a body contact region 1218, a gate dielectric layer 1220, a gate electrode 1221, a field relief dielectric layer 1222, a spacer 1224, a field plate electrode 1226, a gate spacer 1228, silicide layers 1230, an ILD layer 1232, contacts 1234 and metal interconnects 1236.

The LDMOS transistor structure 1200 may be formed using processing similar to that described above with respect to the LDMOS transistor structure 1100. The substrate 1202 is provided, the buried layer 1204 is formed over the substrate 1202, and the epitaxial layer 1206 is formed over the buried layer 1204. The substrate 1202 and the epitaxial layer 1206 are a first conductivity type (e.g., p-type), while the buried layer 1204 is a second conductivity type (e.g., n-type, and thus referred to as an n-type buried layer or NBL). The substrate 1202, the buried layer 1204 and the epitaxial layer 1206 may be formed of silicon, and may also include other semiconducting materials.

The drain drift region 1208, the drain region 1210, the well region 1212, the dwell region 1214, the source region 1216 and the body contact region 1218 may each be formed using one or more ion implant processes (possibly with different energies) followed by optional anneal or thermal drive-in processes, with the use of suitable ion implant masks to form these regions in the locations shown in FIG. 12. The drain drift region 1208, the drain region 1210 and the source region 1216 may be the second conductivity type (e.g., n-type) while the well region 1212 (a shallow well region), the dwell region 1214 and the body contact region 1218 may be the first conductivity type (e.g., p-type).

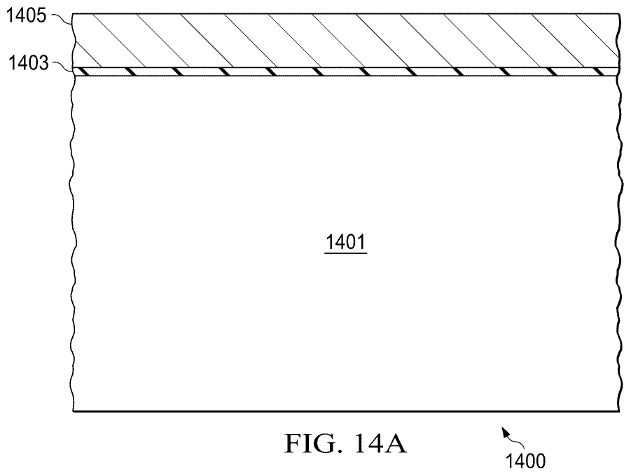

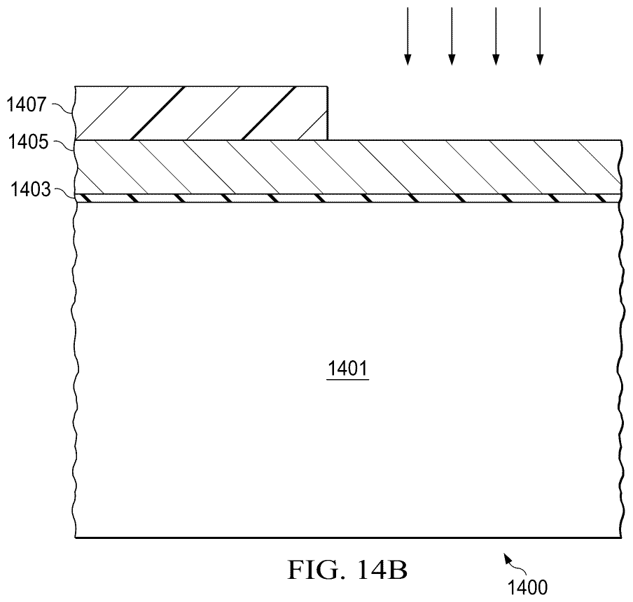

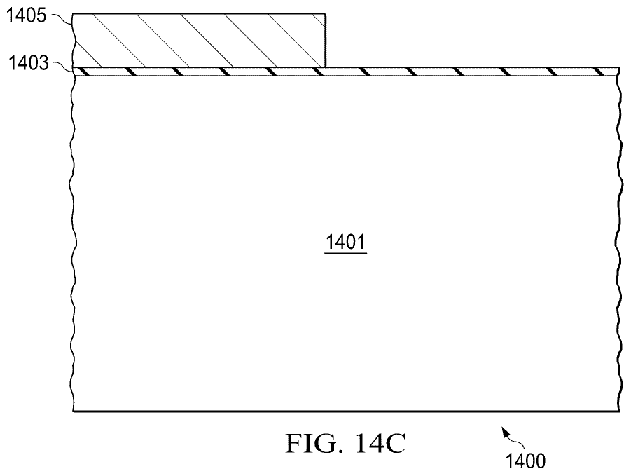

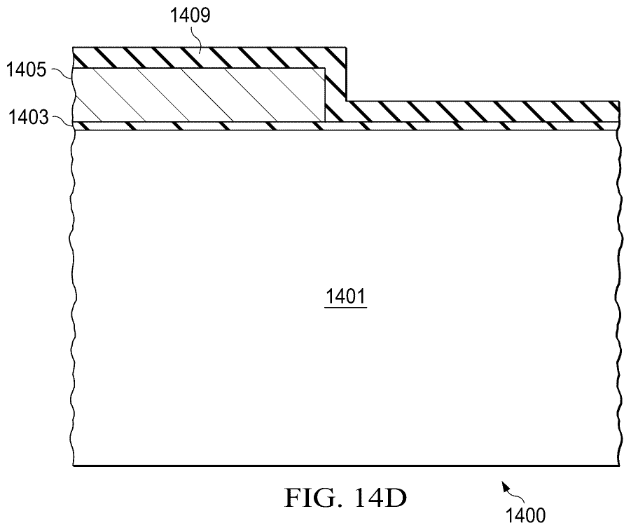

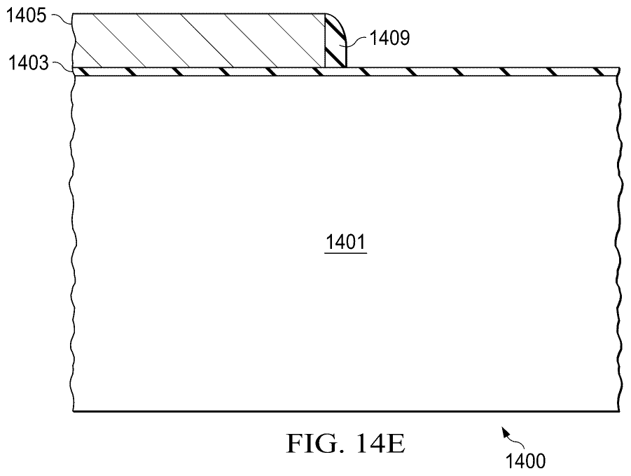

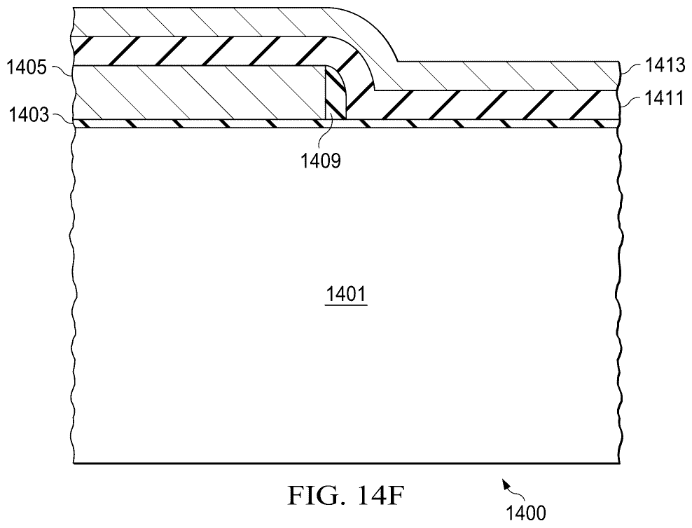

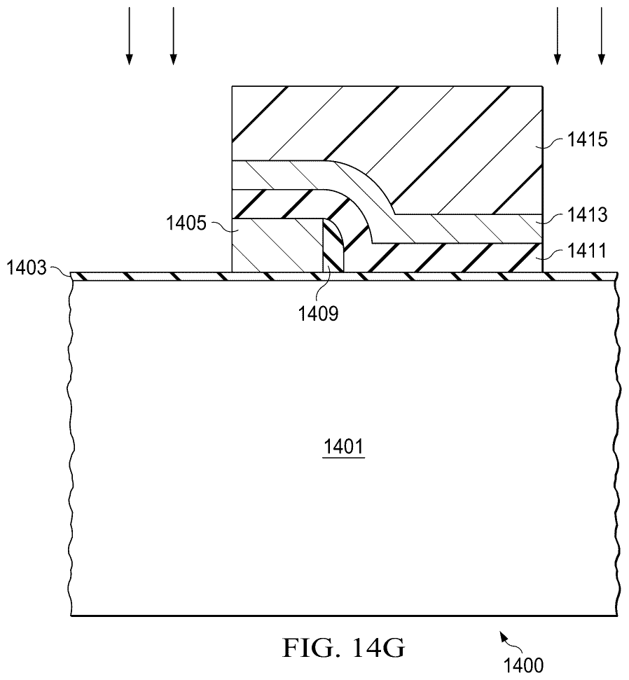

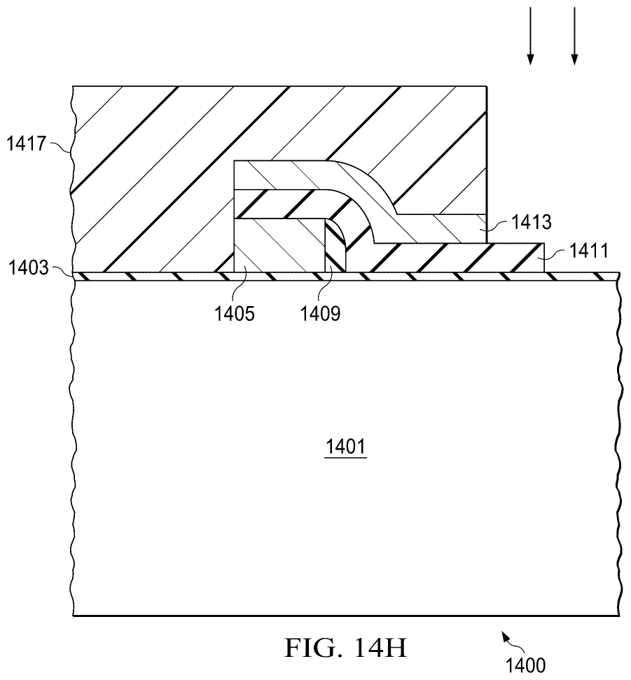

The gate dielectric layer 1220, the gate electrode 1221, the field relief dielectric layer 1222, the spacer 1224 and the field plate electrode 1226 may be formed using the process flow described below with respect to FIGS. 14A-14H.

In the LDMOS transistor structure 1200, the field relief dielectric layer 1222 is disposed between the gate electrode 1221 and the field plate electrode 1226, with the gate electrode 1221 being formed over the epitaxial layer 1206 over the channel region, extending partway over the dwell region 1214 and partway over the drain drift region 1208. The spacer 1224 is formed on a sidewall of the gate electrode 1221, and the field relief dielectric layer 1222 is formed over the gate electrode 1221 and the spacer 1224, and extends over the drain drift region 1208 towards the drain region 1210. The spacer 1224 advantageously helps to shape the electric field to address corner effects as discussed above. The field plate electrode 1226 is formed over a portion of the field relief dielectric layer 1222. The one of the contacts 1234 for the gate is formed in a trench that extends through the field plate electrode 1226 and the field relief dielectric layer 1222 so as to be in contact with both the gate electrode 1221 and the field plate electrode 1226.

Once the field plate electrode 1226 is formed, the gate spacer 1228 is formed. The gate spacer 1228 may be formed by depositing a dielectric material such as silicon nitride, followed by an isotropic etch process such that the gate spacer 1228 is disposed on the sidewalls of the field plate electrode 1226.

The silicide layers 1230 are formed over the drain region 1210, the source region 1216 and the body contact region 1218 (e.g., exposed silicon regions), followed by deposition of the ILD layer 1232, formation of the contacts 1234, and formation of the metal interconnects 1236. The silicide layers 1230, which may be referred to as metal silicide layers, may be formed by deposition of a layer of a metal such as titanium or nickel, which is then heated to form a metal silicide in areas where the metal contacts the epitaxial layer 1206. After the formation of the silicide, the unreacted metal is removed via a wet etch process leaving the silicide layers 1230 in the exposed silicon and polysilicon regions. The ILD layer 1232 may be an oxide deposited using CVD, and may be doped with phosphorus or phosphorus and boron, where the dopants serve as a getter for mobile ions. The contacts 1234 are formed using a pattern and etch process to form contact holes to the underlying layers, the contact holes generally being filled with a metal such as tungsten. The metal interconnects 1236 are formed after the contacts 1234 are formed.

Referring now to FIGS. 13A-13F, a method of fabricating a semiconductor device having a field relief dielectric disposed between first and second gate electrodes is shown.

FIG. 13A shows a semiconductor structure 1300 including an epitaxial layer 1301 (e.g., an example of the epitaxial layer 1106), a gate dielectric layer 1303 (e.g., an example of the gate dielectric layer 1120) formed over the epitaxial layer 1301, and a gate electrode material 1305 formed over the gate dielectric layer 1303. The epitaxial layer 1301 is presented in simplified form, e.g., without expressly showing various implanted regions present in a transistor device. An example of such regions is shown in FIG. 11. The gate dielectric layer 1303 may be formed of a high-k dielectric material. The gate electrode material 1305 has a first work function, and advantageously blocks oxygen diffusion from degrading a high-k interface of the gate dielectric layer 1303 (e.g., over the channel area of the epitaxial layer 1301) during subsequent processes.

FIG. 13B shows the semiconductor structure 1300 of FIG. 13A following patterning of a resist layer 1307 over the gate electrode material 1305, and following removal of portions of the gate electrode material 1305 exposed by the resist layer 1307. It is noted that oxygen diffusion in the area exposed by the resist layer 1307 is not critical, as a thick dielectric layer (e.g., a field relief dielectric layer) will be formed in the area exposed by the resist layer 1307, along with a field plate electrode which provides a region with a high threshold voltage in a resulting LDMOS transistor structure.

FIG. 13C shows the semiconductor structure 1300 of FIG. 13B following removal of the resist layer 1307.

FIG. 13D shows the semiconductor structure 1300 of FIG. 13C following formation of a field relief dielectric material 1309 and a field plate electrode material 1311. The field relief dielectric material 1309 and the field plate electrode material 1311 are blanket deposited over the structure. The field relief dielectric material 1309 may be a low-k material. The field plate electrode material 1311 may have a second work function different than the first work function of the gate electrode material 1305. The field plate electrode material 1311 protects the field relief dielectric material 1309 from poisoning. The thickness of the field relief dielectric material 1309 is defined by the thickness of the gate electrode material 1305, and may be formed using conformal (e.g., CVD) or non-conformal (e.g., PVD) deposition techniques.

FIG. 13E shows the semiconductor structure 1300 of FIG. 13D following patterning of a resist layer 1313 over a portion of the field plate electrode material 1311, and following etching to remove portions of the field plate electrode material 1311, the field relief dielectric material 1309 and the gate electrode material 1305 which are exposed by the resist layer. The gate dielectric layer 1303, formed of a high-k material, provides a good etch stop layer.

FIG. 13F shows the semiconductor structure 1300 of FIG. 13E following removal of the resist layer 1313, patterning of an additional resist layer 1315 over a portion of the field plate electrode material 1311, and following etching to remove portions of the field plate electrode material 1311 exposed by the resist layer 1315. This etching exposes a portion of the top surface of the field relief dielectric material 1309. The structure of FIG. 13F may be subject to further processing to form an LDMOS transistor structure, including various ion implants to form source, drain, drain drift and other well regions, formation of silicide layers, formation of an ILD, and formation of contacts and metal interconnects.

Referring now to FIGS. 14A-14H, a method of fabricating a semiconductor device having a field relief dielectric layer disposed between a gate electrode and a field plate electrode, and with a spacer disposed between the gate electrode and a portion of the field relief dielectric layer, is shown.

FIG. 14A shows a semiconductor structure 1400 including an epitaxial layer 1401 (e.g., an example of the epitaxial layer 1206), a gate dielectric layer 1403 (e.g., an example of the gate dielectric layer 1220) formed over the epitaxial layer 1401, and a gate electrode material 1405 formed over the gate dielectric layer 1403. The epitaxial layer 1401 is presented in simplified form, e.g., without expressly showing various implanted regions present in a transistor device. An example of such regions is shown in FIG. 12. The gate dielectric layer 1403 may be formed of a high-k dielectric material. The gate electrode material 1405 has a first work function, and advantageously blocks oxygen diffusion from degrading a high-k interface of the gate dielectric layer 1403 (e.g., over the channel area of the epitaxial layer 1401) during subsequent processes.

FIG. 14B shows the semiconductor structure 1400 of FIG. 14A following patterning of a resist layer 1407 over the gate electrode material 1405, and following removal of portions of the gate electrode material 1405 exposed by the resist layer 1407. It is noted that oxygen diffusion in the area exposed by the resist layer 1407 is not critical, as a thick dielectric layer (e.g., a field relief dielectric layer) will be formed in the area exposed by the resist layer 1407, along with a field plate electrode which provides a region with a high threshold voltage in a resulting LDMOS transistor structure.

FIG. 14C shows the semiconductor structure 1400 of FIG. 14B following removal of the resist layer 1407.

FIG. 14D shows the semiconductor structure 1400 of FIG. 14C following deposition of a spacer dielectric material 1409 (e.g., for a spacer such as spacer 1224). The spacer dielectric material 1409 may be blanket deposited over the structure. The spacer dielectric material 1409 may have a different dielectric constant than a field relief dielectric layer that is to be formed.

FIG. 14E shows the semiconductor structure 1400 of FIG. 14D following etching of the spacer dielectric material 1409. The etching may be an anisotropic plasma etch process that removes the spacer dielectric material 1409 from horizontal areas, while leaving the spacer dielectric material 1409 on the vertical area (i.e., a sidewall) of the gate electrode material 1405.

FIG. 14F shows the semiconductor structure 1400 of FIG. 14E following formation of a field relief dielectric material 1411 and a field plate electrode material 1413. The field relief dielectric material 1411 and the field plate electrode material 1413 are blanket deposited over the structure. The field relief dielectric material 1411 may be a low-k material. The field plate electrode material 1413 may have a second work function different than the first work function of the gate electrode material 1405. The field plate electrode material 1413 protects the field relief dielectric material 1411 from poisoning. The thickness of the field relief dielectric material 1411 is defined by the thickness of the gate electrode material 1405, and may be formed using conformal (e.g., CVD) or non-conformal (e.g., PVD) deposition techniques.

FIG. 14G shows the semiconductor structure 1400 of FIG. 14F following patterning of a resist layer 1415 over a portion of the field plate electrode material 1413, and following etching to remove portions of the field plate electrode material 1413, the field relief dielectric material 1411 and the gate electrode material 1405 which are exposed by the resist layer. The gate dielectric layer 1403, formed of a high-k material, provides a good etch stop layer.

FIG. 14H shows the semiconductor structure 1400 of FIG. 14G following removal of the resist layer 1415, patterning of an additional resist layer 1417 over a portion of the field plate electrode material 1413, and following etching to remove portions of the field plate electrode material 1413 exposed by the resist layer 1415. This etching exposes a portion of the top surface of the field relief dielectric material 1411. The structure of FIG. 14H may be subject to further processing to form an LDMOS transistor structure, including various ion implants to form source, drain, drain drift and other well regions, formation of silicide layers, formation of an ILD, and formation of contacts and metal interconnects.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A semiconductor device, comprising:
a semiconductor layer;
a source region and a drain region disposed in the semiconductor layer;
a gate electrode over the semiconductor layer between the source region and the drain region;
a gate dielectric layer between the gate electrode and the semiconductor layer;
an insulating layer disposed between a portion of the gate electrode and the gate dielectric layer; and
a spacer disposed between a sidewall of the insulating layer and the gate electrode.

2. The semiconductor device of claim 1, wherein the insulating layer comprises a first dielectric material with a first dielectric constant and the spacer comprises a second dielectric material with a second dielectric constant, the second dielectric constant being different than the first dielectric constant.

3. The semiconductor device of claim 1, wherein the insulating layer has a first height relative to a top surface of the semiconductor layer and the spacer has a second height relative to the top surface of the semiconductor layer, the second height being greater than the first height.

4. The semiconductor device of claim 1, wherein the drain region is disposed within a drain drift region disposed in the semiconductor layer, and wherein the spacer is disposed above a portion of the drain drift region.

5. The semiconductor device of claim 1, wherein the spacer comprises two or more dielectric layers, a first one of the two or more dielectric layers having a first dielectric constant and a second one of the two or more dielectric layers having a second dielectric constant, the second dielectric constant being different than the first dielectric constant.

6. The semiconductor device of claim 1, further comprising a metal layer disposed between the spacer and the gate electrode, wherein the gate electrode has a first work function and the metal layer has a second work function, the second work function being different than the first work function.

7. The semiconductor device of claim 1, further comprising a field plate electrode disposed between a top surface of the insulating layer and the gate electrode, the gate electrode having a first work function and the field plate electrode having a second work function, the second work function being different than the first work function.

8. The semiconductor device of claim 1, further comprising:
a metal layer disposed between the spacer and the gate electrode; and
a field plate electrode disposed between a top surface of the insulating layer and the gate electrode.

9. The semiconductor device of claim 8, wherein the gate electrode has a first work function, the metal layer has a second work function, and the field plate electrode has a third work function, the second work function and the third work function each being different than the first work function.

10. A method of fabricating a semiconductor device, comprising:
forming a source region and a drain region in a semiconductor layer;
forming an insulating layer over a first portion of a semiconductor layer between the source region and the drain region, the insulating layer having a first side toward the source region and a second side toward the drain region;
forming a spacer on the first side of the insulating layer and over a second portion of the semiconductor layer; and
forming a gate electrode over (i) at least a portion of the insulating layer, (ii) the spacer and (iii) a third portion of the semiconductor layer between the spacer and the source region.

11. The method of claim 10, wherein forming the spacer comprises:
depositing a spacer material over the insulating layer and the semiconductor layer; and
etching the spacer material to form the spacer on the first side of the insulating layer.

12. The method of claim 10, wherein forming the spacer comprises:
forming a hard mask over the insulating layer;
depositing a spacer material over the hard mask and the semiconductor layer;
etching the spacer material to form the spacer on the first side of the insulating layer and a first side of the hard mask; and
removing the hard mask.

13. The method of claim 10, wherein forming the spacer comprises:
forming a field plate electrode over the insulating layer;
depositing a spacer material over the field plate electrode and the semiconductor layer; and
etching the spacer material thereby forming the spacer on the first side of the insulating layer and a first side of the field plate electrode.

14. The method of claim 10, wherein forming the spacer comprises:
depositing a first spacer material over the insulating layer and the semiconductor layer;
depositing a second spacer material over the first spacer material; and
etching the first spacer material and the second spacer material to form the spacer on the first side of the insulating layer, the spacer comprising the first spacer material adjacent the first side of the insulating layer and the second spacer material disposed between the first spacer material and the gate electrode.

15. The method of claim 14, wherein the first spacer material comprises a metal with a different work function than the gate electrode, and wherein the second spacer material comprises a dielectric material with a different dielectric constant than the insulating layer.

16. The method of claim 14, wherein the first spacer material comprises a first dielectric material with a first dielectric constant and the second spacer material comprises a second dielectric material with a second dielectric constant, the second dielectric constant being different than the first dielectric constant.

17. A semiconductor device, comprising:
a semiconductor layer;
a source region and a drain region disposed in the semiconductor layer;
a gate electrode over a first portion of the semiconductor layer between the source region and the drain region;
a gate dielectric layer between the gate electrode and the semiconductor layer;
an insulating layer disposed over the gate electrode and a second portion of the semiconductor layer; and
a field plate electrode disposed over a portion of the insulating layer.

18. The semiconductor device of claim 17, wherein the gate electrode comprises a metal material having a first work function and the field plate electrode comprises a metal material having a second work function, the second work function being different than the first work function.

19. The semiconductor device of claim 17, further comprising a spacer disposed between a sidewall of the gate electrode and the insulating layer.

20. The semiconductor device of claim 19, wherein the insulating layer comprises a first dielectric material with a first dielectric constant and the spacer comprises a second dielectric material with a second dielectric constant, the second dielectric constant being different than the first dielectric constant.
